(19) United States
(12) Patent Application Publication
(10) Pub. No.: US 2024/0295809 A1
(43) Pub. Date: Sep. 5, 2024

(54) PELLICLE FRAME, PELLICLE, METHOD OF PRODUCING PELLICLE, AND METHOD OF EVALUATING PELLICLE FRAME

(71) Applicant: MITSUI CHEMICALS, INC., Chuo-ku, Tokyo (JP)

(72) Inventors: Masashi FUJIMURA, Ichihara-shi, Chiba (JP); Akira ISHIKAWA, Ichihara-shi, Chiba (JP); Hisako ISHIKAWA, Ichihara-shi, Chiba (JP); Atsushi OKUBO, Itabashi-ku, Tokyo (JP)

(73) Assignee: MITSUI CHEMICALS, INC., Chuo-ku, Tokyo (JP)

(21) Appl. No.: 18/689,887

(22) PCT Filed: Sep. 12, 2022
(86) PCT No.: PCT/JP2022/034110

§ 371 Date: Mar. 7, 2024

(30) Foreign Application Priority Data
Sep. 13, 2021 (JP) 2021-148631

(51) Int. Cl. G03F 1/64

(52) U.S. Cl. CPC G03F 1/64

(57) ABSTRACT

The present invention provides a pellicle frame (excluding a pellicle frame containing quartz glass) having a rectangular shape, which has: one end face to be provided with an adhesive layer capable of adhering to a photomask; and the other end face for supporting a pellicle film. The one end face has an amount of twist Δd of 10 μm or less. The amount of twist Δd of the one end face indicates the maximum value of the distance between a virtual plane that passes through three points, of four points at four corners of the one end face, and one remaining point.

### TECHNICAL FIELD

The present disclosure relates to a pellicle frame, a pellicle, a method of producing a pellicle, and a method of evaluating a pellicle frame.

### BACKGROUND ART

The refinement of semiconductor integrated circuits has been driven by photolithography. In photolithography, a photomask on one surface of which a pattern is formed is used. A pellicle is attached to the photomask in order to prevent the adhesion of foreign substances such as dust on the surface of the photomask.

Attaching a pellicle to the photomask may lead to a change in the flatness of the photomask, possibly causing problems in the pattern to be printed on a wafer due to focus displacement during exposure. Further, there are risks that problems in the overlay accuracy of the photomask may occur due to a change in the shape of the pattern. Therefore, attempts to achieve a lower TIR (Total Indicator Reading) value, which indicates the flatness of a pellicle frame, have been done in order to reduce the deformation of the photomask.

Patent Document 1 discloses a pellicle which does not impair the flatness of a photomask, even when the pellicle is attached to the photomask. The pellicle disclosed in Patent Document 1 includes a pellicle frame. The TIR value of the pellicle frame on the side to be attached to a photomask is 30 μm or less. The TIR value of the pellicle frame on the side of a pellicle film is 15 μm or less.

Patent Document 2 discloses a pellicle capable of reducing the deformation of a photomask to a minimum level without any special consideration on the flatness of the pellicle frame thereof, even when the pellicle is attached to the photomask. The pellicle disclosed in Patent Document 2 includes a mask-adhesion layer (hereinafter, also referred to as “adhesive layer for a photomask”) for attaching the pellicle to a mask. The adhesive layer for a photomask has a flat surface. A TIR value of the flat surface of the adhesive layer for a photomask is 15 μm or less.

Patent Document 1: Japanese Patent Application Laid-Open (JP-A) No. 2008-256925

Patent Document 2: JP-A No. 2009-025560

### SUMMARY OF THE INVENTION

### Technical Problem

In the pellicle disclosed in Patent Document 1, however, the twisting of the pellicle frame included in the pellicle is not considered. The twisting of the pellicle frame is mainly due to a residual stress which occurs during the production of the pellicle frame. There is a risk that twisting is present in the pellicle frame, even in a case in which the TIR value of the pellicle frame on the side to be attached to a photomask is 30 μm or less. In a case in which twisting is present in the pellicle frame, a pressure (load) for flattening the surface of the adhesive layer for a photomask may fail to be evenly distributed over the entire adhesive layer for a photomask, at the time of forming the adhesive layer for a photomask on the pellicle frame. As a result, the TIR value of the adhesive layer for a photomask may increase. Thus, when the pellicle disclosed in Patent Document 1 is attached to a photomask, there is a risk that the photomask may be distorted.

In the pellicle disclosed in Patent Document 2, the thickness of the adhesive layer for a photomask is not considered. The larger the thickness of the adhesive layer for a photomask is, the less the TIR value of the adhesive layer for a photomask is affected by the TIR value of the pellicle frame on the side to be attached to a photomask. Therefore, the TIR value of the adhesive layer for a photomask can be more easily controlled to be closer to the TIR value of a photomask.

In recent years, however, it is expected that the level required for the amount of outgas from adhesive layers for photomasks will rise regardless of using an ArF excimer laser (wavelength: 193 nm) or EUV (Extreme Ultra Violet) light (wavelength: from 3 nm to 30) nm), in order to achieve a further refinement of semiconductor integrated circuits. Further, it is expected that adhesive layers for photomasks are required to have a smaller thickness. In a case in which EUV light having a wavelength shorter than that of the ArF excimer laser is used as a light source for exposure, in particular, the exposure is carried out in a vacuum environment. Therefore, a further decrease in the thickness of adhesive layers for photomasks is strongly demanded. Adhesive layers for photomasks are required to have, for example, a thickness of from 10 μm to 500 μm.

The present disclosure has been made in view of the above-mentioned circumstances.

An object of one embodiment of the present disclosure is to provide a pellicle frame which allows for reducing the distortion of a photomask due to attaching a pellicle thereto, a pellicle including the same, and a method of producing the pellicle.

An object of another embodiment of the present disclosure is to provide a method of evaluating a pellicle frame, which allows for measuring the amount of twist of an end face of the pellicle frame with high accuracy.

### Solution to Problem

Means for achieving the above-described objects include the following embodiments.

<1> A pellicle frame (excluding a pellicle frame containing quartz glass) having a rectangular shape, the pellicle frame having:
one end face to be provided with an adhesive layer capable of adhering to a photomask: and
another end face for supporting a pellicle film:
wherein the one end face has an amount of twist Δd of 10 μm or less, and
wherein the amount of twist Δd of the one end face indicates a maximum value of a distance between a virtual plane that passes through three points, of four points at four corners of the one end face, and one remaining point.
   <2> The pellicle frame according to <1> described above, wherein the other end face has an amount of twist Δd of 10 μm or less, and
wherein the amount of twist Δd of the other end face indicates a maximum value of a distance between a virtual plane that passes through three points, of four points at four corners of the other end face, and one remaining point.
   <3> The pellicle frame according to <1> or <2> described above, wherein the pellicle frame includes a metal.
   <4> The pellicle frame according to <1> or <2> described above, wherein the pellicle frame includes at least one selected from the group consisting of aluminum, titanium, stainless steel, a carbon-based material, a resin, silicon and a ceramic-based material.
   <5> The pellicle frame according to <1> or <2> described above, wherein the pellicle frame has a Young's modulus of 90 GPa or more.
   <6> The pellicle frame according to any one of <1> to <5> described above, wherein the amount of twist Δd of the one end face is 1 μm or more.
   <7> The pellicle frame according to any one of <1> to <6> described above, wherein the one end face has a TIR value of 30 μm or less.
   <8> The pellicle frame according to any one of <1> to <7> described above, wherein the other end face has a TIR value of 30 μm or less
   <9> A pellicle including:
the pellicle frame according to any one of <1> to <8> described above:
the adhesive layer provided on the one end face; and
the pellicle film supported on the other end face.
   <10> A method of producing a pellicle, the method including:
a step of preparing the pellicle frame according to any one of <1> to <8> described above; and
a step of forming the adhesive layer, by coating a coating composition on the one end face to form a coating layer, heating the coating layer in a state in which the coating layer is brought into contact with a flat surface of a flattening article, and then baking the coating layer:
wherein the adhesive layer has a thickness of from 10 μm to 500 μm, and
wherein the flat surface has a TIR value of less than 10 μm.
   <11> The method of producing a pellicle according to <10>, including a step of fixing three points, of four points at four corners of the one end face of the pellicle frame having a rectangular shape, and applying a force to one remaining point.
   <12> A method of evaluating a pellicle frame having a rectangular shape, the pellicle frame having: one end face to be provided with an adhesive layer capable of adhering to a photomask: and another end face for supporting a pellicle film:
wherein the method includes measuring an amount of twist Δd of the one end face, and
wherein the amount of twist Δd indicates a maximum value of a distance between a virtual plane that passes through three points, of four points at four corners of the one end face, and one remaining point.

### Advantageous Effects of Invention

The present disclosure enables to provide a pellicle frame which allows for reducing the distortion of a photomask due to attaching a pellicle thereto, a pellicle including the same, and a method of producing the pellicle.

Further, the present disclosure enables to provide a method of evaluating a pellicle frame, which allows for measuring the amount of twist of an end face of the pellicle frame with high accuracy.

### BRIEF DESCRIPTION OF THE DRAWINGS

FIG. 1 is a schematic cross-sectional view showing a cross section of a pellicle according to a first embodiment of the present disclosure.

FIG. 2 is a schematic cross-sectional view showing a cross section of a pellicle according to a second embodiment of the present disclosure.

FIG. 3 is a schematic cross-sectional view showing a cross section of a pellicle frame with an adhesive layer, according to Example 1.

### DESCRIPTION OF EMBODIMENTS

In the present disclosure, any numerical range indicated using the expression “from * to” represents a range in which numerical values described before and after the “to” are included in the range as a minimum value and a maximum value, respectively.

In a numerical range described in stages, in the present disclosure, an upper limit value or a lower limit value described in a certain numerical range may be replaced with an upper limit value or a lower limit value in another numerical range described in stages. Further, in a numerical range described in the present disclosure, an upper limit value or a lower limit value in a certain numerical range may be replaced with a value shown in Examples.

In the present disclosure, any combination of two or more preferred embodiments is a more preferred embodiment.

In the present disclosure, the amount of each component, in a case in which a plurality of substances corresponding to each component are present, refers to the total amount of the plurality of substances, unless otherwise specified.

Further, in the present disclosure, the definition of the term “step” includes not only an independent step, but also a step which is not clearly distinguishable from another step, as long as the intended purpose of the step is achieved.

In the present disclosure, the term “(meth)acrylate” refers to acrylate or methacrylate.

### (1) Pellicle Frame

A pellicle frame according to the present disclosure is a pellicle frame (excluding a pellicle frame containing quartz glass) having a rectangular-shape, the pellicle frame having: one end face to be provided with an adhesive layer capable of adhering to a photomask: and the other end face for supporting a pellicle film. The one end face has an amount of twist Ad of 10 μm or less. The amount of twist Δd of the one end face indicates the maximum value of the distance between a virtual plane that passes through three points, of four points at the four corners of the one end face, and one remaining point.

In the present disclosure, the expression “the amount of twist Δd of the one end face indicates the maximum value of the distance between a virtual plane that passes through three points, of four points at the four corners of the one end face, and one remaining point” means that the amount of twist Δd of the one end face indicates the maximum value of the following first distance, second distance, third distance and fourth distance. When the four points at the four corners of the one end face are respectively defined as point C1. point C2, point C3 and point C4, the first distance refers to the shortest distance between the virtual plane that passes through the point C1, the point C2 and the point C3, and the point C4. The second distance refers to the shortest distance between the virtual plane that passes through the point C1, the point C2 and the point C4, and the point C3. The third distance refers to the shortest distance between the virtual plane that passes through the point C1, the point C3 and the point C4, and the point C2. The fourth distance refers to the shortest distance between the virtual plane that passes through the point C2, the point C3 and the point C4, and the point C1.

Each of the first distance, the second distance, the third distance and the fourth distance is measured by the same method as that used in Examples.

Hereinafter, the one end face to be provided with an adhesive layer (hereinafter, also referred to as “adhesive layer for a photomask”) capable of adhering to a photomask, of the pellicle frame, is also referred to as “end face for a photomask”, and the other end face for supporting a pellicle film, of the pellicle frame, is also referred to as “end face for a pellicle film”.

Since the pellicle frame according to the present disclosure has the configuration described above, it is possible to control the TIR value of the adhesive layer for a photomask, to a value (preferably less than 10 μm) close to the TIR value of a photomask, even in a case in which the thickness of the adhesive layer for a photomask is decreased (for example, within the range of from 10 μm to 500 μm). In general, the TIR value of a photomask is about several μm. As a result, the pellicle frame according to the present disclosure can reduce the distortion of a photomask due to attaching the resulting pellicle thereto, even in a case in which the adhesive layer for a photomask has a small thickness, and can further reduce the distortion of a photomask, even in a case in which the adhesive layer for a photomask has an equivalent thickness.

Since the pellicle frame according to the present disclosure has the configuration described above, the pellicle frame can be controlled to have a flattening rate higher (for example, 0.5 or more) than that of a conventional pellicle frame. In other words, the pellicle frame according to the present disclosure enables to form an adhesive layer for a photomask, which layer has a higher flatness, even in a case in which the end face for a photomask does not have a high flatness. The flattening rate is represented by the following Equation (1).

Equation (1): flattening rate=1−(TIR value of adhesive layer for a photomask/TIR value of end face for a photomask)

In Equation (1), the TIR value of the adhesive layer for a photomask is measured by the same method as that used in Examples. The TIR value of the end face for a photomask is measured by the same method as that used in Examples.

The pellicle frame has a rectangular shape. Specifically, the pellicle frame is a rectangular cylindrical object. The pellicle frame has a through-hole. The through-hole refers to a space through which light transmitted through a pellicle film passes in order to reach a photomask.

The pellicle frame may have a vent hole. The vent hole communicates between the internal space of the pellicle and the exterior space of the pellicle, when the pellicle frame is attached to a photomask. The term “internal space of the pellicle” refers to a space surrounded by the pellicle and the photomask. The term “exterior space of the pellicle” refers to a space that is not surrounded by the pellicle and the photomask.

The rectangular shape may be a square or a rectangle. The term “rectangular” refers to a right-angled quadrilateral. The term “square” refers to a shape in which all of the four sides constituting a rectangle have the same length. The term “rectangle” refers to a rectangle excluding a square.

### (1. 1) End Face For Photomask

The amount of twist Δd of the end face for a photomask preferably is 1 μm or more. As described above, the amount of twist Δd of the end face for a photomask indicates the maximum value of the distance between a virtual plane that passes through three points, of four points at the four corners of the end face for a photomask, and one remaining point.

When the amount of twist Δd of the end face for a photomask is 1 μm or more, the production cost of the pellicle frame can further be reduced. To decrease the amount of twist μd of the end face for a photomask, it is necessary, for example, to carve out the pellicle frame by polishing a raw material plate, which is a raw material of the pellicle frame, with a relatively low polishing efficiency, as will be described later. Therefore, adjusting the amount of twist Δd of the end face for a photomask to 1 μm or more makes it possible to achieve an improved yield, as compared to the case in which the amount of twist Δd of the end face for a photomask is adjusted to less than 1 μm. As a result, the production cost of the pellicle frame can further be reduced.

The upper limit of the amount of twist Δd of the end face for a photomask is 10 μm, preferably 8 μm or less, more preferably 6 μm or less, and still more preferably 4 μm or less, from the viewpoint of reducing the distortion of a photomask due to attaching the resulting pellicle thereto.

The lower limit of the amount of twist Δd of the end face for a photomask is preferably 1 μm or more, more preferably 2 μm or more, and still more preferably 4 μm or more, from the viewpoint of reducing the production cost of the pellicle frame.

From these points of view; the amount of twist Δd of the end face for a photomask is preferably from 1 μm to 10 μm, more preferably from 2 μm to 8 μm, and still more preferably from 3 μm to 6 μm.

The amount of twist Δd of the end face for a photomask is measured as follows. Specifically, the pellicle frame is placed on a surface plate such that the end face (namely, the end face for a pellicle film) of the pellicle frame different from the end face (namely, the end face for a photomask) (hereinafter, also referred to as “end face on the measurement side”) on the side whose amount of twist is measured, of the pellicle frame, faces the surface plate. The height from the surface plate to each of the four points at the four corners of the end face on the measurement side, is measured using a 3D displacement meter. Subsequently, the measured values of the heights of the four points are used to obtain a virtual plane that passes through three points of the four points, and the shortest distance (hereinafter, also referred to as “first shortest distance”) between the thus obtained virtual plane and one remaining point is calculated. Since there are four patterns for obtaining a virtual plane from the four points, four first shortest distances are calculated. The maximum value of the four first shortest distances is defined as the amount of twist Δd of the end face on the measurement side.

Specifically, when the four corners of the end face on the measurement side are respectively defined as the points C1, C2, C3 and C4, the amount of twist Δd of the end face on the measurement side indicates the maximum value of the following first distance, second distance, third distance and fourth distance. The first distance refers to the shortest distance between the virtual plane that passes through the point C1, the point C2 and the point C3, and the point C4. The second distance refers to the shortest distance between the virtual plane that passes through the point C1, the point C2 and the point C4, and the point C3. The third distance refers to the shortest distance between the virtual plane that passes through the point C1, the point C3 and the point C4, and the point C2. The fourth distance refers to the shortest distance between the virtual plane that passes through the point C2, the point C3 and the point C4, and the point C1.

The TIR value of the end face for a photomask is preferably 30 μm or less. The TIR value of the end face for a photomask indicates the difference between the maximum value and the minimum value of the differences in height between the height of a least squares plane calculated using a plurality of predetermined measurement points in the end face for a photomask, and the heights of the respective plurality of measurement points.

When the TIR value of the end face for a photomask is 30 μm or less, the adhesive layer for a photomask to be provided on the end face for a photomask, is more likely to have a lower TIR value. As a result, when the resulting pellicle is attached to a photomask, the distortion of the photomask can be reduced.

The upper limit of the TIR value of the end face for a photomask is more preferably 25 μm or less, and still more preferably 20 μm or less, from the viewpoint of reducing the occurrence of twisting of the pellicle film included in the resulting pellicle due to the twisting of the pellicle frame.

The lower limit of the TIR value of the end face for a photomask is not particularly limited, and is preferably 1 μm or more, more preferably 2 μm or more, still more preferably 3 μm or more, and particularly preferably 4 μm or more.

From these points of view; the TIR value of the end face for a photomask is preferably from 1 μm to 30 μm, more preferably from 2 μm to 25 μm, still more preferably from 3 μm to 20 μm, and particularly preferably from 4 μm to 15 μm.

The TIR value of the end face for a photomask is measured as follows. Specifically, the pellicle frame is placed on a surface plate such that the end face (namely, the end face for a pellicle film) of the pellicle frame different from the end face (namely, the end face for a photomask) (hereinafter, also referred to as “end face on the measurement side”) on the side whose TIR value is measured, of the pellicle frame, faces the surface plate. The height from the surface plate to each of predetermined measurement points on the end face on the measurement side, is measured by a 3D displacement meter. The predetermined measurement points are defined as four points at the four corners of the end face on the measurement side, and points which are set at 2.5 mm intervals from one point of the four corners toward another point of the four corners, on each of the sides between the four corners. It is noted, however, in a case in which the interval (hereinafter, also referred to as “corner interval”) between one point (hereinafter, also referred to as “corner point”) of the four corners and a point adjacent to the corner point is 2.5 mm or less, the point adjacent to the corner point is defined as a point which is set such that the corner interval is less than 2.5 mm.

Subsequently, the least squares plane calculated using the measured values of the heights of all the predetermined points is obtained. The measurement point having the maximum difference in height, of the differences in height between a plurality of measurement points located on the side opposite to the side of the surface plate with respect to the least squares plane, and the least squares plane, is identified as “first measurement point”. The measurement point having the maximum difference in height, of the differences in height between a plurality of measurement points located on the side of the surface plate with respect to the least squares plane, and the least squares plane, is identified as “second measurement point”. The sum of the difference in height from the least squares plane at the first measurement point and the difference in height from the least squares plane at the second measurement point, is defined as the TIR value.

### (1. 2) End Face for Pellicle Film

The end face for a pellicle film preferably has an amount of twist Δd of 10 μm or less. The amount of twist Δd of the end face for a pellicle film indicates the maximum value of the distance between a virtual plane that passes through three points, of four points at four corners of the end face for a pellicle film, and one remaining point.

When the amount of twist Δd of the end face for a pellicle film is 10 μm or less, it is possible to reduce the occurrence of twisting of the pellicle film included in the resulting pellicle due to the twisting of the pellicle frame. As a result, the occurrence of poor exposure due to the twisting of the pellicle film can be reduced in the resulting pellicle.

The upper limit of the amount of twist Δd of the end face for a pellicle film is more preferably 8 μm or less, and still more preferably 6 μm or less, from the viewpoint of reducing the occurrence of twisting of the pellicle film.

The lower limit of the amount of twist Δd of the end face for a pellicle film is preferably 1 μm or more, more preferably 2 μm or more, and still more preferably 3 μm or more, from the viewpoint of reducing the production cost of the pellicle frame.

From these points of view; the amount of twist Δd of the end face for a pellicle film is preferably from 1 μm to 10 μm, more preferably from 2 μm to 8 μm, and still more preferably from 3 μm to 6 μm.

The amount of twist Δd of the end face for a pellicle film is measured by the same method as the above-described method (the method of measuring the amount of twist Δd of the end face for a photomask).

The end face for a pellicle film preferably has a TIR value of 30 μm or less. The TIR value of the end face for a pellicle film indicates the difference between the maximum value and the minimum value of the differences in height between the height of the least squares plane calculated using a plurality of predetermined measurement points in the end face for a pellicle film, and the heights of the respective plurality of measurement points.

When the TIR value of the end face for a pellicle film is 30 μm or less, it is possible to reduce the occurrence of twisting of the pellicle film included in the resulting pellicle due to the twisting of the pellicle frame. As a result, the occurrence of poor exposure due to the twisting of the pellicle film can be reduced, when the resulting pellicle is attached to a photomask.

The upper limit of the TIR value of the end face for a pellicle film is more preferably 25 μm or less, and still more preferably 20 μm or less, from the viewpoint of reducing the occurrence of twisting of the pellicle film.

The lower limit of the TIR value of the end face for a pellicle film is preferably 1 μm or more, more preferably 2 μm or more, and still more preferably 3 μm or more, from the viewpoint of reducing the production cost of the pellicle frame.

From these points of view; the TIR value of the end face for a pellicle film is preferably from 1 μm to 30 μm, more preferably from 2 μm to 25 μm, and still more preferably from 3 μm to 20 μm.

The TIR value of the end face for a pellicle film is measured by the same method as the above-described method (the method of measuring TIR value of the end face for a photomask).

### (1. 3) Material of Pellicle Frame

The definition of the pellicle frame according to the present disclosure does not include a pellicle frame containing quartz glass. Quartz glass has a Young's modulus of 70 GPa.

The pellicle frame preferably has a Young's modulus of 90 GPa or more. A pellicle film is supported on the end face for a pellicle film of the pellicle frame, in a tensioned state. When the Young's modulus of the pellicle frame is 90 GPa or more, it is possible to reduce the occurrence of deformation of the pellicle frame due to the tension of the pellicle film.

Examples of materials having a Young's modulus of 90 GPa or more include titanium, titanium alloys, and silicon. Glass generally has a Young's modulus of 70 GPa.

The Young's modulus of the pellicle frame is a value measured by a tensile test (JIS G0567J). In a case in which the material of the pellicle frame is a resin, however, the Young's modulus of the pellicle frame is a value measured by a three-point flexural test (JIS K7171). Whether or not the material of the pellicle frame is a resin is determined by whether or not the material of the pellicle frame thermally decomposes at 550° C.

The upper limit of the Young's modulus of the pellicle frame is not particularly limited, and is preferably 300 GPa, and more preferably 250 GPa.

The Young's modulus of the pellicle frame is preferably 60 GPa or less. By this arrangement, the occurrence of distortion of a photomask can be reduced when the resulting pellicle is attached to the photomask, even in a case in which the amount of twist Δd of the end face for a photomask of a pellicle frame having a Young's modulus of 60 GPa or less is equivalent to that of a pellicle frame having a Young's modulus of more than 60 GPa.

Examples of materials having a Young's modulus of 60 GPa or less include magnesium, magnesium alloys, polyethylene terephthalate (PET) resins, and resins.

The Young's modulus is a value measured by a tensile test (JIS G0567J). In a case in which the material of the pellicle frame is a resin, however, the Young's modulus is a value measured by a three-point flexural test (JIS K7171). Whether or not the material of the pellicle frame is a resin is determined by whether or not the material of the pellicle frame thermally decomposes at 550° C.

The pellicle frame preferably contains a metal.

The metal may be a pure metal or an alloy: A pure metal consists of a single metal element. Examples of the pure metal include aluminum and titanium. An alloy is composed of a plurality of metal elements, or composed of a metal element(s) and a non-metal element(s). Examples of the alloy include stainless steel, magnesium alloys, steel, carbon steel, and invar.

The pellicle frame preferably contains at least one selected from the group consisting of aluminum, titanium, stainless steel, a carbon-based material, a resin, silicon and a ceramic-based material.

Examples of the resin include polyethylene.

Examples of the ceramic-based material include silicon nitride (SiN), silicon carbide (SiC), and alumina (Al₂O₃).

### (1. 4) Configuration

The pellicle frame according to the present disclosure may be a single-unit product or an assembled product. The “single-unit product” refers to a product obtained by carving out from one raw material plate, as will be described later. The “assembled product” refers to a product obtained by integrating a plurality of members. A plurality of members can be integrated, for example, by a method using a known adhesive, or a method using a fastening part. Examples of the fastening part include bolts, nuts, screws, rivets, and pins.

In a case in which the pellicle frame is an assembled product, the assembled product may be composed of a plurality of members made of different materials. In a case in which the pellicle frame is an assembled product, it is preferred that the member (hereinafter, also referred to as “frame member for an adhesive layer) including the end face for a photomask has a Young's modulus of 60 GPa or less, and the member (hereinafter, also referred to as “film-supporting frame member) including the end face for a pellicle film has a Young's modulus of 90 GPa or more. This makes it possible to reduce the deformation of the pellicle frame due to the distortion of the film-supporting frame caused by the tension of the pellicle film, in the resulting assembled product of the pellicle frame. Further, the occurrence of distortion of a photomask can be reduced when the resulting pellicle is attached to the photomask, even in a case in which the amount of twist Δd of the end face for a photomask of the assembled product of the pellicle frame is equivalent to that of a frame member for an adhesive layer having a Young's modulus of more than 60 GPa.

### (2) Pellicle

A pellicle according to the present disclosure includes: the pellicle frame according to the present disclosure: an adhesive layer for a photomask: and a pellicle film. The adhesive layer for a photomask is provided on the end face for a photomask of the pellicle frame. The pellicle film is supported on the end face for a pellicle film of the pellicle frame.

### (2. 1) Adhesive Layer for Photomask

The pellicle according to the present disclosure includes an adhesive layer for a photomask.

The adhesive layer for a photomask allows the pellicle according to the present disclosure to adhere to a photomask.

The adhesive layer for a photomask is a gel-like viscoelastic body. The adhesive layer for a photomask preferably has a viscosity and a cohesive force. The term “viscosity” refers to liquid-like properties to get wet upon coming into contact with a photomask as an adherend. The term “cohesive force” refers to solid-like properties to resist being peeled from the photomask.

The adhesive layer for a photomask preferably has a glass transition temperature Tg of higher than −25° C. but lower than 10° C. By this arrangement, the adhesive layer for a photomask has an adhesive force within an operating temperature range (for example, 20° C. or higher) of the pellicle, and the pellicle is less likely to peel off from the photomask even when exposed to a high temperature environment.

The lower limit of the glass transition temperature Tg of the adhesive layer for a photomask is preferably higher than −25° C., more preferably −22° C. or higher, still more preferably −20° C. or higher, and most preferably −18° C. or higher, from the viewpoint of making the pellicle less likely to peel off from the photomask even when exposed to a high temperature environment.

The upper limit of the glass transition temperature Tg of the adhesive layer for a photomask is preferably lower than 10° C., more preferably 5° C. or lower, and still more preferably 0° C. or lower, from the viewpoint of imparting adhesiveness at normal temperature.

The glass transition temperature (Tg) of the adhesive layer for a photomask is measured in accordance with JIS K7112. Specifically, the glass transition temperature (Tg) of the adhesive layer for a photomask is measured by differential scanning calorimetry (DSC) at a temperature rise rate of 20° C./min and in a nitrogen atmosphere.

The thickness of the adhesive layer for a photomask is not particularly limited, and is preferably from 10 μm to 500 μm, more preferably from 100 μm to 400 μm, and still more preferably from 200 μm to 300 μm. When the thickness of the adhesive layer for a photomask is within the range described above, the amount of outgas from the adhesive layer for a photomask is less likely to have an impact.

The thickness of the adhesive layer for a photomask is measured by the same method as that used in Examples.

The adhesive layer for a photomask preferably has a TIR value of less than 10 μm. The TIR value of the end face for a photomask indicates the difference between the maximum value and the minimum value of the differences in height between the height of the least squares plane calculated using a plurality of predetermined measurement points in the end face for a photomask, and the heights of the respective plurality of measurement points.

The TIR value of a photomask is about several μm. When the TIR value of the adhesive layer for a photomask is less than 10 μm, which is close to the TIR value of a photomask, the change in the flatness of a photomask can be reduced upon attaching the pellicle to the photomask. As a result, the distortion of the photomask due to attaching the pellicle can be reduced.

As described above, the TIR value of the adhesive layer for a photomask is measured by the same method as that used in Examples.

The adhesive layer for a photomask is formed, for example, by subjecting a coating composition to various types of processing, such as coating, heating, drying and curing, as will be described later.

### (2. 2) Pellicle Film

The pellicle according to the present disclosure includes a pellicle film.

The pellicle film prevents the adhesion of foreign substances to the surface of a photomask, and transmits exposure light upon exposure. Foreign substances include dust. Examples of the exposure light include deep-ultraviolet (DUV) light and EUV. EUV refers to light having a wavelength of from 2 nm to 30 nm.

The pellicle film covers the entire opening of the through-hole of the pellicle frame on the side of one end face (end face for a pellicle film). The pellicle film may be directly supported, or supported via a film adhesion layer, on one end face of the pellicle frame. The film adhesion layer may be a cured product of a known adhesive.

The pellicle film preferably has a film thickness of from 1 nm to 400 nm.

The material of the pellicle film is not particularly limited, and may be, for example, a carbon-based material, SiN, or polysilicon. Examples of the carbon-based material include carbon nanotubes (hereinafter, each also referred to as “CNT”). In particular, the material of the pellicle film preferably includes a CNT. The CNT may be a single-wall CNT or a multi-wall CNT.

The pellicle film may have a nonwoven fabric structure. The nonwoven fabric structure is formed, for example, by a CNT in the form of fibers.

The pellicle film may be supported on the pellicle frame indirectly via an adhesive layer for a pellicle film, or supported directly on the pellicle frame.

The adhesive for forming the adhesive layer for a pellicle film may be, for example, an acrylic resin adhesive, an epoxy resin adhesive, a polyimide resin adhesive, a silicone resin adhesive, an inorganic adhesive, a double-sided adhesive tape, a polyolefin-based adhesive, or a hydrogenated styrene-based adhesive.

In particular, the adhesive for a pellicle film is preferably at least one selected from the group consisting of a silicone resin adhesive, an acrylic resin adhesive, a hydrogenated styrene-based adhesive and an epoxy resin adhesive, from the viewpoints of the ease of coating processing and the ease of curing processing.

In the present disclosure, the adhesive for a pellicle film is a concept including not only an adhesive, but also an adhesive.

The thickness of the adhesive layer for a pellicle film is not particularly limited. The thickness of the adhesive layer for a pellicle film is, for example, from 10 μm to 1 mm.

### (2. 4) Exposure Original Plate

The pellicle according to the present disclosure may be included in an exposure original plate.

The exposure original plate includes a photomask and a pellicle. The photomask is an original plate for forming a circuit pattern. The photomask has a pattern. The pellicle is attached to the surface of the photomask on the side having a pattern.

The photomask includes, for example, a support substrate, a reflective layer and an absorber layer, which are not necessarily layered one on another in the order mentioned. When the absorber layer partially absorbs light (for example, EUV), a desired image is formed on a sensitive substrate (for example, a semiconductor substrate with a photoresist film). The reflective layer may be, for example, a multilayer film of molybdenum (Mo) and silicon (Si). The material of the absorber layer may be a material having a high absorption of light such as EUV. Examples of the material having a high absorption of light such as EUV include chromium (Cr) and tantalum nitride.

### (2. 5) Exposure Apparatus

The pellicle according to the present disclosure may be included in an exposure apparatus.

The exposure apparatus includes a light source, the exposure original plate described above, and an optical system. The light source emits exposure light. The optical system leads the exposure light emitted from the light source to the exposure original plate. The exposure original plate is arranged such that the exposure light emitted from the light source is transmitted through the pellicle film to be irradiated to the photomask.

The exposure apparatus can form a fine pattern (for example, a pattern having a line width of 32 nm or less) by EUV or the like, and in addition, can perform a pattern exposure in which poor resolution due to foreign substances is reduced, even in the case of using EUV which is more susceptible to the problem of poor resolution due to foreign substances.

The exposure light is preferably EUV. Since EUV has a short wavelength, EUV is more easily absorbed by a gas such as oxygen or nitrogen. Therefore, exposure by EUV light is performed in a vacuum environment.

### (2. 6) One Example of Pellicle

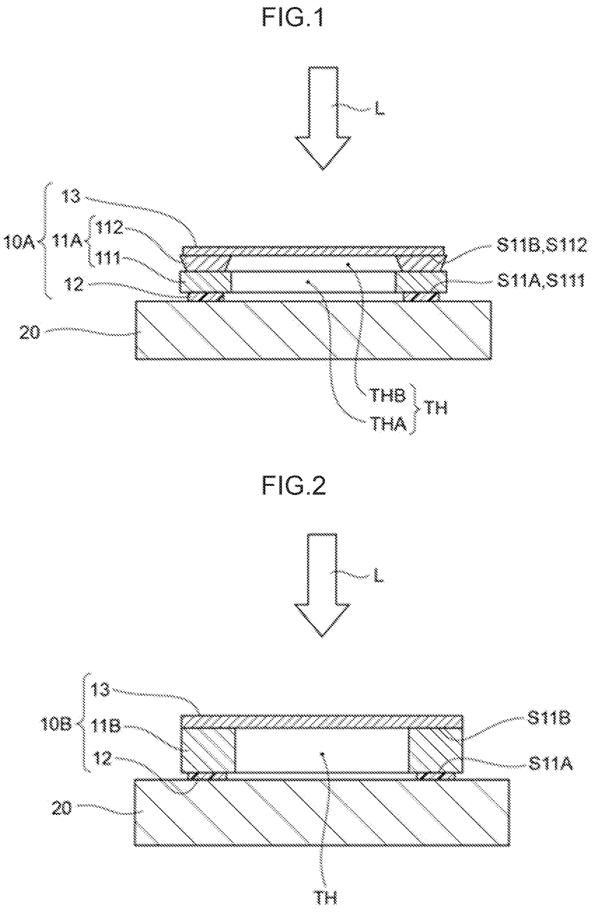

Next, one example of the pellicle according to the present disclosure will be described with reference to FIG. 1 and FIG. 2. FIG. 1 is a cross-sectional view of a pellicle 10A according to the first embodiment of the present disclosure. FIG. 2 is a cross-sectional view of a pellicle 10B according to the second embodiment of the present disclosure. In the figures, the same or corresponding portions are denoted by the same reference numerals, and the description thereof will not be repeated.

### (2. 6. 1) First Embodiment

As shown in FIG. 1, the pellicle 10A according to the first embodiment of the present disclosure is attached onto the surface of a photomask 20 before use.

The pellicle 10A includes a pellicle frame 11A, an adhesive layer 12 for a photomask, and a pellicle film 13. The pellicle frame 11A has an end face S11A for a photomask, and an end face S11B for a pellicle film. The adhesive layer 12 for a photomask is provided on the end face S11A for a photomask. The pellicle film 13 is supported on the end face S11B for a pellicle film via a known film adhesion layer.

The pellicle frame 11A is a rectangular cylindrical object. The pellicle frame 11A has a through-hole TH. The end face S11A for a photomask of the pellicle frame 11A has an amount of twist Δd of 10 μm or less.

In the first embodiment, the pellicle frame 11A is an assembled product. The pellicle frame 11A includes a frame member 111 for an adhesive layer, and a film-supporting frame member 112. The film-supporting frame member 112 is placed on the frame member 111 for an adhesive layer. The frame member 111 for an adhesive layer and the film-supporting frame member 112 are integrated by a known adhesive. While the frame member 111 for an adhesive layer and the film-supporting frame member 112 are integrated by a known adhesive, in the first embodiment, these members may be integrated by a fastening part.

The frame member 111 for an adhesive layer is a rectangular cylindrical object, as with the pellicle frame 11A. The frame member 111 for an adhesive layer has a through-hole THA. The through-hole THA constitutes a part of the through-hole TH of the pellicle frame 11A.

The frame member 111 for an adhesive layer has an end face S111. The end face S111 constitutes the end face S11A for a photomask of the pellicle frame 11A.

In the first embodiment, the frame member 111 for an adhesive layer has a Young's modulus of 60 GPa or less. Therefore, the occurrence of distortion of the photomask 20 can be reduced when the pellicle is attached to the photomask 20, even in a case in which the amount of twist Δd of the end face S11A for a photomask of the pellicle frame 11A is equivalent to that of a frame member for an adhesive layer having a Young's modulus of more than 60 GPa.

The film-supporting frame member 112 is a rectangular cylindrical object, as with the pellicle frame 11A. The film-supporting frame member 112 has a through-hole THB. The through-hole THB constitutes a part of the through-hole TH of the pellicle frame 11A.

The film-supporting frame member 112 has an end face S112. The end face S112 constitutes the end face S11B for a pellicle film of the pellicle frame 11A.

In the first embodiment, the film-supporting frame member 112 has a Young's modulus of 90 GPa or more. Therefore, it is possible to reduce the deformation of the pellicle frame 11A due to the distortion of the film-supporting frame member 112 caused by the tension of the pellicle film 13.

The pellicle 10A is suitably used for exposure using exposure light having a short wavelength (such as EUV light, or light having a wavelength even shorter than that of EUV light). In the case of exposure in which exposure light L is EUV light, the exposure is carried out in a vacuum atmosphere, since EUV light is more easily absorbed by a gas such as oxygen or nitrogen.

### (2. 6. 2) Second Embodiment

As shown in FIG. 2, the pellicle 10B according to the second embodiment of the present disclosure is attached onto the surface of a photomask 20 before use.

The pellicle 10B includes a pellicle frame 11B, an adhesive layer 12 for a photomask, and a pellicle film 13. The pellicle frame 11B has an end face S11A for a photomask, and an end face S11B for a pellicle film. The adhesive layer 12 for a photomask is provided on the end face S11A for a photomask. The pellicle film 13 is supported on the end face S11B for a pellicle film via a known film adhesion layer.

The pellicle frame 11B is a rectangular cylindrical object. The pellicle frame 11B has a through-hole TH. The end face S11A for a photomask of the pellicle frame 11B has an amount of twist Δd of 10 μm or less.

In the second embodiment, the pellicle frame 11B is a single-unit product.

The pellicle 10B is suitably used for exposure using exposure light L having a short wavelength. In the case of exposure in which the exposure light L is EUV light, the exposure is carried out in a vacuum atmosphere, since EUV light is more easily absorbed by a gas such as oxygen or nitrogen.

### (3) Method of Producing Pellicle

A method of producing a pellicle according to the present disclosure includes a preparation step to be described later, and a step of forming an adhesive layer to be described later. The preparation step and the step of forming an adhesive layer are performed in the order mentioned. This makes it possible to obtain a pellicle in which the TIR value of the adhesive layer for a photomask is closer to that of a photomask, even in a case in which the adhesive layer for a photomask has a small thickness.

### (3. 1) Preparation Step

The method of producing a pellicle according to the present disclosure includes a preparation step.

In the preparation step, the pellicle frame according to the present disclosure is prepared. This makes it possible to obtain a pellicle frame which enables to form an adhesive layer for a photomask, which layer has a TIR value closer to that of a photomask, even in a case in which the adhesive layer for a photomask has a small thickness.

The pellicle frame can be prepared, for example, by a method such as a carving method. For example, in the carving method, a raw material plate, which is the raw material of the pellicle frame, is polished by a known method with a relatively low polishing efficiency, to carve out the pellicle frame. This allows for reducing the residual stress occurring in the pellicle frame, making it possible to decrease the amount of twist Δd of the end face for a photomask. The “polishing efficiency” is represented by the polished amount (removed thickness) (μm) per unit hour (min). The “relatively low polishing efficiency” may be, for example, 1,000 nm/min or less, preferably 500 nm or less/min or less, and more preferably 300 nm or less/min. The raw material plate may be a plate-like object.

At least one main surface of the raw material plate is preferably subjected to mirror finishing by a known method, so as to achieve a TIR value of 30 μm or less. This makes it possible to obtain a pellicle frame in which at least one of the end face for a photomask or the end face for a pellicle film has a TIR value of 30 μm or less.

### (3. 2) Correction Step

The method of producing a pellicle according to the present disclosure may include a correction step. The correction step is carried out after performing the preparation step and before performing the step of forming an adhesive layer.

In the correction step, the end faces of the pellicle frame are corrected to decrease the amount of twist μd. The pellicle frame can be corrected by a method (hereinafter, also referred to as “correction method”) of fixing three points, of four points at the four corners of one end face of the pellicle frame having a rectangular shape, and applying a force to one remaining point. Examples of the correction method include a method in which the following (a) and (b) are performed in the order mentioned. (a) The pellicle frame is placed on a surface plate such that three points, of four points at the four corners of one end face of the pellicle frame, are in contact with the surface plate.

(b) A load is applied to the other end face, such that one remaining point of the four corners of the one end face of the pellicle frame moves toward the direction in which the surface plate exists.

### (3. 2) Step of Forming Adhesive Layer

In the step of forming an adhesive layer, a coating composition is coated on the end face for a photomask to form a coating layer, the coating layer is heated in a state in which the coating layer is brought into contact with a flat surface of a flattening article, and then the coating layer is baked to form an adhesive layer for a photomask. The adhesive layer for a photomask has a thickness of from 10 μm to 500 μm. Each flat surface has a TIR value of less than 10 μm. The TIR value of the flat surface is measured by the same method as that used in Examples.

### (3.2. 1) Coating

In the step of forming an adhesive layer, a coating composition is coated on the end face for a photomask, to form a coating layer on the end face for a photomask. As a result, a pellicle frame with a coating layer can be obtained.

It is preferred that the coating composition is coated only on the region of the central portion of each of the sides between the four corners of the end face for a photomask, not over the entire end face for a photomask. In other words, it is preferred that the coating composition is not coated on the regions including the marginal portion on the side of the through-hole of the pellicle frame and the marginal portion on the side opposite to the through-hole of the pellicle frame, of each of the sides between the four corners. By this arrangement, the adhesive layer for a photomask is less likely to overflow to the sides of the inner and outer peripheral walls of the pellicle frame as compared to the case of coating the coating composition over the entire end face for a photomask, when the resulting pellicle is attached to a photomask. Therefore, the adhesive layer for a photomask is less likely to be exposed. As a result, the amount of outgas to be generated can further be reduced.

The coating composition can be coated on the end face for a photomask of the pellicle frame by any method without particular limitation, and examples thereof include a method using a dispenser.

The coating layer of the coating composition can have any thickness as long as the resulting adhesive layer for a photomask has a thickness of from 10 μm to 500 μm, and preferably from 100 μm to 400 μm.

### (3. 2. 2) Flattening

In the step of forming an adhesive layer, the coating layer of the pellicle frame with a coating layer is heated in a state in which the coating layer is brought into contact with a flat surface of a flattening article. The thickness of the coating layer immediately after the coating of the coating composition usually varies depending on the portion of the coating layer. By heating the coating layer of the pellicle frame with a coating layer in a state in which the coating layer is brought into contact with the flat surface of the flattening article, the flatness of the thickness of the coating layer of the pellicle frame with a coating layer can be improved.

Hereinafter, an article in which the flattening article is brought into contact with the coating layer of the pellicle frame with a coating layer is also referred to as “first contact article”.

The coating layer can be brought into contact with the flat surface of the flattening article by any method without particular limitation, and examples thereof include an upside-down method, and a placing method. In the placing method, the pellicle frame with a coating layer is placed, in a state where an adhesive protective film (hereinafter, also referred to as “liner”) is pasted on the surface of the coating layer, such that the coating layer pasted with the liner, of the pellicle frame, and the flat surface of the flattening article are in contact with each other, with the coating layer of the pellicle frame with a coating layer facing downward direction (direction of gravity). In the upside-down method, the pellicle frame with a coating layer is arranged, in a state where a liner is pasted on the surface of the coating layer, such that the coating layer pasted with the liner, of the pellicle frame, and the flat surface of the flattening article are in contact with each other, with the coating layer of the pellicle frame with a coating layer facing upward direction (direction opposite to the direction of gravity). In either case of using the upside-down method or the placing method, a flattening article may further be brought into contact with the end face for a pellicle film of the pellicle frame with a coating layer. In particular, the placing method is preferred from the viewpoint of facilitating the heating of the coating layer when heating the coating layer by a hot plate.

In a case in which the coating layer is brought into contact with the flat surface via the liner, the pressure (load) to be uniformly applied to the entire coating layer is not particularly limited, and is preferably from 10 g/cm² to 1,000 g/cm², more preferably from 100 g/cm² to 800 g/cm², and still more preferably from 300 g/cm² to 600 g/cm², from the viewpoint of decreasing the TIR value of the adhesive layer for a photomask while reducing the distortion of the pellicle frame.

The flat surface of the flattening article has a TIR value of less than 10 μm. This makes it possible to adjust the TIR value of the adhesive layer for a photomask to less than 10 μm. The TIR value of the flat surface of the flattening article is preferably 5 μm or less, more preferably 3 μm or less, and a value closer to 0 μm is more preferred, from the viewpoint of forming an adhesive layer for a photomask, which layer has a lower TIR value. The flattening article may be, for example, a glass substrate.

The coating layer of the pellicle frame with a coating layer can be heated in a state in which the coating layer is brought into contact with the flat surface via the liner, by any method without particular limitation, and examples thereof include a method using an oven, and a method using a hot plate. In the method using an oven, the first contact article is placed in an oven, and the first contact article itself is heated, thereby heating the coating layer. In the method using a hot plate, for example, the first contact article is placed on a hot plate such that the flattening article which is in contact with the coating layer of the first contact article via the liner, is in contact with the plate of the hot plate, and the coating layer is heated through the flattening article, thereby heating the coating layer.

In the case of heating the coating layer using an oven, the interior of the oven is controlled to a set temperature of preferably from 70° C. to 130° C., and more preferably from 80° C. to 110° C. The set temperature of the interior of the oven refers to the temperature inside the oven. In the case of using an oven, the coating layer is heated preferably for a period of time from 10 seconds to 15 minutes, and more preferably from one minute to 10 minutes.

In the case of heating the coating layer using a hot plate, the hot plate is controlled to a set temperature of from 70° C. to 130° C., and more preferably from 80° C. to 110° C. The set temperature of the hot plate refers to the surface temperature of the hot plate. In the case of using a hot plate, the coating layer is heated preferably for a period of time from 10 seconds to 15 minutes, and more preferably from one minute to 10 minutes.

### (3. 2. 3) Baking

In the step of forming an adhesive layer, the coating layer is baked, after heating and flattening the coating layer. This allows for removing at least one of a solvent(s) or residual monomers from the coating layer. As a result, the adhesive layer for a photomask is formed from the coating layer. In other words, a pellicle frame with an adhesive layer is obtained. The pellicle frame with an adhesive layer includes the pellicle frame, and the adhesive layer for a photomask. The adhesive layer for a photomask is formed on the end face for a photomask. The adhesive layer for a photomask has a thickness of from 10 μm to 500 μm. The thickness of the adhesive layer for a photomask is measured by the same method as that used in Examples.

In the step of forming an adhesive layer, for example, the flattening article is removed from the first contact article after heating, to obtain the pellicle frame with a coating layer. The resulting pellicle frame with a coating layer is placed on a substrate such that the coating layer of the pellicle frame with a coating layer is in contact with the substrate via the liner. Hereinafter, an article composed of the substrate, and the pellicle frame with a coating layer placed on the substrate, is also referred to as “second contact article”. A substrate may be placed on the coating layer of the second contact article, such that the substrate is in contact with the end face for a pellicle film of the second contact article.

The coating layer of the pellicle frame with a coating layer can be baked by any method without particular limitation, and examples thereof include a method using an oven. In the method using an oven, the second contact article is placed in the oven, and the second contact article itself is heated, thereby baking the coating layer.

The temperature and the period of time for baking the coating layer can be selected as appropriate, depending on the type of the adhesive, the boiling points of the solvent(s) and the residual monomers, and the like. In the case of baking the coating layer using an oven, the interior of the oven is controlled to a set temperature of preferably from 70° C. to 130° C., and more preferably from 80° C. to 120° C. In the case of using an oven, the coating layer is baked preferably for a period of time from 12 hours to 120 hours, and more preferably from 24 hours to 72 hours.

### (3. 2. 4) Coating Composition

The coating composition contains compounds selected from various polymers, solvents, crosslinking agents, catalysts, initiators and the like, depending on the adhesive layer for a photomask to be formed. The coating composition is a precursor of an adhesive composition. In other words, the adhesive composition (adhesive layer for a photomask) is formed by curing the coating composition.

### (3.2. 5) Adhesive Composition

The adhesive composition is not particularly limited, and may be, for example, an acrylic adhesive, a silicone-based adhesive, a styrene-based adhesive, a urethane-based adhesive, or an olefin-based adhesive. In particular, the adhesive composition is preferably an acrylic adhesive from the viewpoint of reducing the amount of outgas generated from the pellicle, and is preferably a styrene-based adhesive from the viewpoint of reducing the distortion of a photomask.

The styrene-based adhesive and the acrylic adhesive will be described below:

### (3. 2. 5. 1) Styrene-based Adhesive

The styrene-based adhesive contains a styrene-based thermoplastic elastomer (A) and a tackifying resin (B) (namely, a resin for imparting adhesiveness).

### (3. 2. 5. 1. 1) Styrene-based Thermoplastic Elastomer (A)

The styrene-based adhesive contains a styrene-based thermoplastic elastomer (A).

The styrene-based thermoplastic elastomer (A) does not contain an ester binding site within a molecular skeleton. Therefore, the styrene-based thermoplastic elastomer (A) has an excellent hydrolysis resistance, and includes a soft segment and a hard segment within the same molecular skeleton. This allows the styrene-based adhesive to have an excellent flexibility and mechanical strength.

The styrene-based thermoplastic elastomer (A) is a polymer containing a structural unit derived from styrene. The styrene-based thermoplastic elastomer (A) is preferably a block copolymer of styrene and an olefin other than styrene. The olefin other than styrene is preferably a monomer capable of forming a side chain having a bulky branched structure within a polymer block, more preferably isoprene, 4-methyl-1-pentene or the like, and still more preferably isoprene.

The total proportion of structural units derived from styrene, contained in the styrene-based thermoplastic elastomer (A), is preferably 35% by mass or less, and more preferably 20% by mass or less, with respect to the total amount of the styrene-based thermoplastic elastomer (A). When the total proportion of structural units derived from styrene is within the range described above, compatibility with various types of additives is less likely to deteriorate, and the styrene-based thermoplastic elastomer (A) and the additives are less likely to be separated from each other.

The styrene-based thermoplastic elastomer (A) preferably includes a triblock copolymer (hereinafter, also referred to as “SIS”), or a hydrogenated product of a triblock copolymer (hereinafter, also referred to as “H-SIS”). The SIS includes a first polystyrene block, a polyisoprene block having an isopropenyl group (1-methylethenyl group (—C(═CH₂)CH₃) in a side chain, and a second polystyrene block.

The “hydrogenated product of a triblock copolymer” refers to one in which preferably 90% or more, more preferably 95% or more of unsaturated bonds in the “polyisoprene block”, of the three polymer blocks included in the SIS, are hydrogenated. The rate of hydrogenation is measured using a nuclear magnetic resonance apparatus (NMR).

The SIS may be a commercially available product. Examples of the commercially available product of the SIS include “HYBRAR 5127” (brand name: manufactured by Kuraray Co., Ltd.), and “HYBRAR 5215” (brand name: manufactured by Kuraray Co., Ltd.).

The H-SIS may be a commercially available product. Examples of the commercially available product of the H-SIS include “HYBRAR 7125” (brand name: manufactured by Kuraray Co., Ltd.), and “HYBRAR 7311” (brand name: manufactured by Kuraray Co., Ltd.).

### (3. 2. 5. 1. 2) Tackifying Resin (B)

The styrene-based adhesive contains a tackifying resin (B).

The tackifying resin (B) is preferably compatible with the styrene-based thermoplastic elastomer (A). The tackifying resin (B) is preferably rosin or a derivative thereof, a polyterpene resin or a hydride thereof, a terpene phenol resin or a hydride thereof, an aromatic-modified terpene resin or a hydride thereof, a coumarone-indene resin, an aliphatic petroleum resin, an alicyclic petroleum resin or a hydride thereof, an aromatic petroleum resin or a hydride thereof, an aliphatic-aromatic copolymer-based petroleum resin, or a dicyclopentadiene-based petroleum resin or a hydride thereof, from the viewpoint of being highly compatible with the polyisoprene block of the SIS or the H-SIS. In particular, the tackifying resin (B) is preferably rosin or a derivative thereof, a polyterpene resin or a hydride thereof, an aliphatic petroleum resin, or an alicyclic petroleum resin or a hydride thereof: more preferably rosin or a derivative thereof, an aliphatic petroleum resin, or an alicyclic petroleum resin or a hydride thereof: and particularly preferably a hydride of an alicyclic petroleum resin.

The tackifying resin (B) may be a commercially available product. Examples of the commercially available product of the rosin or a derivative thereof include “PINECRYSTAL”, “SUPER ESTER”, and “TAMANOL” (brand names: all of the above, manufactured by Arakawa Chemical Industries, Ltd.). Examples of the commercially available product of the polyterpene resin, the terpene phenol resin, the aromatic-modified terpene resin, and hydrides of these resins, include “YS RESIN”, “YS POLYSTER”, and “CLEARON” (all of the above, manufactured by Yasuhara Chemical Co., Ltd.). Examples of the commercially available product of the aliphatic petroleum resin, the alicyclic petroleum resin or a hydride thereof, the aromatic petroleum resin or a hydride thereof, the aliphatic-aromatic copolymer-based petroleum resin, and the dicyclopentadiene-based petroleum resin or a hydride thereof include “ALCON” (manufactured by Arakawa Chemical Industries, Ltd.), “HIGHLETS” (manufactured by Mitsui Chemicals, Inc.), “I-MARV” (manufactured by Idemitsu Kosan Co., Ltd.), “QUINTONE” (manufactured by Zeon Corporation), and “ESCOREZ” (manufactured by Tonex Co., Ltd.). The tackifying resin (B) can be used singly, or in combination of two or more kinds thereof.

The amount of the tackifying resin (B) to be incorporated is from 20 parts by mass to 150 parts by mass with respect to 100 parts by mass of the styrene-based thermoplastic elastomer (A). When the amount of the tackifying resin (B) to be incorporated is within the range described above, the resulting styrene-based adhesive is less likely to be sticky. Further, such an incorporated amount is less likely to cause adhesive residue, when the adhesive layer for a photomask composed of the styrene-based adhesive is peeled off from the photomask.

### (3. 2. 5. 1. 3) Other Components

The styrene-based adhesive may further contain another component(s).

The other component(s) may be, for example, a softener, a wax, and/or the like.

The softener may be any material capable of imparting flexibility to the styrene-based thermoplastic elastomer (A). Examples of the softener include poly butenes, hydrogenated poly butenes, unsaturated poly butenes, aliphatic hydrocarbons, and acrylic polymers. The amount of the softener to be added is preferably from 20 parts by mass to 300 parts by mass, and more preferably from 50 to 200 parts by mass, with respect to 100 parts by mass of the styrene-based thermoplastic elastomer (A).

The wax is a component capable of adjusting the hardness of the styrene-based adhesive. For example, the wax is preferably a highly elastic material, and more preferably a polyethylene wax or a polypropylene wax. The amount of the wax to be added is preferably from 20 parts by mass to 200 parts by mass, and more preferably from 50 parts by mass to 100 parts by mass, with respect to 100 parts by mass of the styrene-based thermoplastic elastomer (A).

### (3. 2. 5. 2) Acrylic Adhesive

The acrylic adhesive contains a (meth)acrylic acid alkyl ester copolymer.

### (3. 2. 5. 2. 1) (Meth)acrylic Acid Alkyl Ester Copolymer

The (meth)acrylic acid alkyl ester copolymer preferably includes a copolymer of:
a (meth)acrylic acid alkyl ester monomer: and
a monomer (hereinafter, also referred to as “functional group-containing monomer”) containing a functional group having a reactivity with at least one of an isocyanate group, an epoxy group, or an acid anhydride.

Hereinafter, the copolymer of a (meth)acrylic acid alkyl ester monomer and a functional group-containing monomer is also referred to as “the copolymer”.

When the acrylic adhesive contains the (meth)acrylic acid alkyl ester copolymer, the resulting pellicle is less likely to peel off from the photomask even in the case of being exposed to a high temperature environment (for example, a temperature environment of 60° C., or of higher than 60° C.), and the occurrence of adhesive residue can be reduced.

The term “adhesive residue” refers to a phenomenon in which at least a portion of the adhesive layer for a photomask remains on the photomask after the pellicle has been peeled off from the photomask.

The (meth)acrylic acid alkyl ester copolymer preferably has a weight average molecular weight (Mw) of from 30,000 to 2,500,000, more preferably from 50,000 to 1,500,000, and still more preferably from 70,000 to 1,200,000. When the upper limit of the weight average molecular weight (Mw) of the (meth)acrylic acid alkyl ester copolymer is 2,500,000 or less, solution viscosity can be controlled to the range that facilitates processing, even in a case in which the solid concentration of the coating composition is increased. The upper limit of the weight average molecular weight (Mw) of the (meth)acrylic acid alkyl ester copolymer is preferably 2,500,000 or less, more preferably 1,500,000 or less, and still more preferably 1,200,000 or less.

When the lower limit of the weight average molecular weight (Mw) of the (meth)acrylic acid alkyl ester copolymer is 30,000 or more, the pellicle is less likely to peel off from the photomask even in the case of being exposed to a high temperature environment (for example, 60° C.), and the occurrence of adhesive residue can be reduced. The lower limit of the weight average molecular weight (Mw) of the (meth)acrylic acid alkyl ester copolymer is preferably 30,000 or more, more preferably 50,000 or more, and still more preferably 70,000 or more.

The weight average molecular weight (Mw) of the (meth)acrylic acid alkyl ester copolymer is measured by GPC (gel permeation chromatography).

In general, for example, a higher monomer concentration during a polymerization reaction tends to result in a higher weight average molecular weight (Mw), and a lower amount of polymerization initiator or a lower polymerization temperature tends to result in a higher weight average molecular weight (Mw). The weight average molecular weight (Mw) can be controlled by adjusting the monomer concentration, the amount of polymerization initiator, and the polymerization temperature.

The (meth)acrylic acid alkyl ester copolymer preferably has a number average molecular weight (Mn) of from 5,000 to 500,000, more preferably from 8,000 to 300,000, still more preferably from 10,000 to 200,000, and most preferably from 20,000 to 200,000.

When the upper limit of the number average molecular weight (Mn) of the (meth)acrylic acid alkyl ester copolymer is 500,000 or less, the solution viscosity can be controlled to the range that facilitates processing, even in a case in which the solid concentration of the coating composition is increased. The upper limit of the number average molecular weight (Mn) of the (meth)acrylic acid alkyl ester copolymer is preferably 500,000 or less, more preferably 300,000 or less, and still more preferably 200,000 or less. When the lower limit of the number average molecular weight (Mn) of the (meth)acrylic acid alkyl ester copolymer is 5,000 or more, the pellicle is less likely to peel off from the photomask even in the case of being exposed to a high temperature environment (for example, 60° C.), and the occurrence of adhesive residue can be reduced. The lower limit of the number average molecular weight (Mn) of the (meth)acrylic acid alkyl ester copolymer is preferably 5,000 or more, more preferably 8,000 or more, still more preferably 10,000 or more, and most preferably 20,000 or more.

The number average molecular weight (Mn) of the (meth)acrylic acid alkyl ester copolymer is measured by the same method as the method of measuring the weight average molecular weight (Mw) of the (meth)acrylic acid alkyl ester copolymer described above.

The ratio “weight average molecular weight (Mw)/number average molecular weight (Mn)” (hereinafter, also referred to as “Mw/Mn”) of the (meth)acrylic acid alkyl ester copolymer is preferably from 1.0 to 10.0, more preferably from 2.5 to 9.0, still more preferably from 2.5 to 8.0, and most preferably from 3.0 to 7.0. When the ratio Mw/Mn is within the range described above, the (meth)acrylic acid alkyl ester copolymer can be produced easily, and the occurrence of adhesive residue can be reduced.

When the upper limit of the ratio Mw/Mn is 10.0 or less, the occurrence of adhesive residue can be reduced. The upper limit of the ratio Mw/Mn is preferably 10.0 or less, more preferably 9.0 or less, still more preferably 8.0 or less, and most preferably 7.0 or less.

When the lower limit of the ratio Mw/Mn is 1.0 or more, the (meth)acrylic acid alkyl ester copolymer can be produced easily. The lower limit of the ratio Mw/Mn is preferably 1.0 or more, more preferably 2.0 or more, still more preferably 2.5 or more, and most preferably 3.0 or more.

The (meth)acrylic acid alkyl ester monomer preferably includes a (meth)acrylic acid alkyl ester monomer containing an alkyl group having from 1 to 14 carbon atoms. The (meth)acrylic acid alkyl ester monomer containing an alkyl group having from 1 to 14 carbon atoms may be, for example, a (meth)acrylic acid ester monomer of a linear aliphatic alcohol, or a (meth)acrylic acid ester monomer of a branched aliphatic alcohol.

Examples of the (meth)acrylic acid ester monomer of a linear aliphatic alcohol include methyl (meth)acrylate, ethyl (meth)acrylate, butyl (meth)acrylate, propyl (meth)acrylate, hexyl (meth)acrylate, octyl (meth)acrylate, decyl (meth)acrylate, (meth)acrylic acid dodecyl, and lauryl (meth)acrylate.

Examples of the (meth)acrylic acid ester monomer of a branched aliphatic alcohol include isobutyl (meth)acrylate, isoamyl (meth)acrylate. 2-ethylhexyl (meth)acrylate, isooctyl (meth)acrylate, and isononyl (meth)acrylate. These monomers may be used singly, or in combination of two or more kinds thereof.

Of these, the (meth)acrylic acid alkyl ester monomer preferably contains at least one of an alkyl group having from 1 to 3 carbon atoms or an alicyclic alkyl group.

Hereinafter, the (meth)acrylic acid alkyl ester monomer containing at least one of an alkyl group having from 1 to 3 carbon atoms or an alicyclic alkyl group, is also referred to as “high-Tg monomer”. The term “Tg” refers to the glass transition temperature.

To further reduce the amount of outgas to be generated, the (meth)acrylic acid alkyl ester monomer is more preferably an acrylic acid alkyl ester monomer containing an alkyl group having from 1 to 3 carbon atoms, or an alicyclic alkyl group, and still more preferably an acrylic acid alkyl ester monomer containing an alkyl group having from 1 to 3 carbon atoms. In a case in which the (meth)acrylic acid alkyl ester monomer is an acrylic acid alkyl ester monomer containing an alicyclic alkyl group, the alicyclic alkyl group preferably has from 5 to 10 carbon atoms from the viewpoint of the ease of availability.

When the (meth)acrylic acid alkyl ester monomer includes a high-Tg monomer, the pellicle is less likely to peel off from the photomask even in the case of being exposed to a high temperature atmosphere.

Specific examples of the high-Tg monomer include methyl acrylate, ethyl acrylate, propyl acrylate, isopropyl acrylate, cyclohexyl acrylate, dicyclopentanyl acry late, methyl methacrylate, ethyl methacry late, propyl methacry late, isopropyl methacrylate, cyclohexyl methacrylate, and dicyclopentanyl methacrylate.

The content of the (meth)acrylic acid alkyl ester monomer is preferably from 80 parts by mass to 99.5 parts by mass, more preferably from 85 parts by mass to 99.5 parts by mass. and still more preferably from 87 parts by mass to 99.5 parts by mass, with respect to 100 parts by mass of the total amount of the monomers constituting the copolymer.

When the content of the (meth)acrylic acid alkyl ester monomer is within the range of from 80 parts by mass to 99.5 parts by mass, an adequate adhesive force can be achieved.

The functional group-containing monomer is a monomer copolymerizable with the (meth)acrylic acid alkyl ester monomer. The functional group-containing monomer contains a functional group having a reactivity with at least one of an isocyanate group, an epoxy group, or an acid anhydride.

The functional group-containing monomer may be, for example, a carboxy group-containing monomer, a hydroxy group-containing monomer, or an epoxy group-containing monomer.

Examples of the carboxy group-containing monomer include (meth)acrylic acid, itaconic acid, (meth)acrylic acid-itaconic acid, maleic acid, and crotonic acid.

Examples of the hydroxy group-containing monomer include 2-hydroxyethyl (meth)acrylate, 3-hydroxypropyl (meth)acrylate, 2-hydroxypropyl (meth)acrylate, and 4-hydroxy butyl (meth)acrylate.

Examples of the epoxy group-containing monomer include glycidyl (meth)acrylate.

These monomers may be used singly, or in combination of two or more kinds thereof.

The functional group-containing monomer preferably includes a hydroxy group-containing (meth)acrylic acid containing a hydroxyalkyl group having from 2 to 4 carbon atoms, or glycidyl (meth)acrylate which is an epoxy group-containing monomer, particularly from the viewpoints of copolymerizability, general versatility and the like. Examples of the hydroxy group-containing (meth)acrylic acid containing a hydroxy alkyl group having from 2 to 4 carbon atoms include 2-hydroxyethyl (meth)acrylate, 2-hydroxypropyl (meth)acrylate, 2-hydroxy butyl (meth)acrylate, and 4-hydroxy butyl (meth)acrylate.

The content of the functional group-containing monomer is preferably, for example, from 0.5 parts by mass to 20 parts by mass, with respect to 100 parts by mass of the total amount of the monomers constituting the copolymer.

From the viewpoint of improving the adhesive force of the adhesive layer for a photomask, the lower limit of the content of the functional group-containing monomer is more preferably 1 part by mass or more, still more preferably 2 parts by mass or more, and particularly preferably 3 parts by mass or more, with respect to 100 parts by mass of the total amount of the monomers constituting the (meth)acrylic acid alkyl ester copolymer.

From the viewpoint of controlling the adhesive force of the adhesive layer for a photomask to a moderate level, the upper limit of the content of the functional group-containing monomer is more preferably 15 parts by mass or less, and still more preferably 10 parts by mass or less, with respect to 100 parts by mass of the total amount of the monomers constituting the (meth)acrylic acid alkyl ester copolymer.

### (3. 2. 5. 2. 2) Polymerization Method

The (meth)acrylic acid alkyl ester copolymer can be polymerized by any polymerization method without particular limitation, and examples thereof include solution polymerization, bulk polymerization, emulsion polymerization, and various types of radical polymerization.

The (meth)acrylic acid alkyl ester copolymer obtained by any of these polymerization methods may be a random copolymer, a block copolymer, a graft copolymer, or the like.

### (3. 2. 5. 2. 3) Polymerization Solvent

A reaction solution contains a polymerization solvent.

In the solution polymerization, for example, a solvent such as propyl acetate, ethyl acetate or toluene can be used as the polymerization solvent. This allows the viscosity of the resulting copolymer solution to be adjusted. As a result, the thickness and width of the coating composition can be more easily controlled at the time of performing the polymerization.

As a diluting solvent, propyl acetate, acetone, ethyl acetate, toluene or the like can be used, for example.

The viscosity of the copolymer solution is preferably 1,000 Pa·s or less, more preferably 500 Pa·s or less, and still more preferably 200 Pa·s or less.

The viscosity of the copolymer solution is the viscosity thereof when the temperature of the copolymer solution is 25° C., and can be measured by a Type E viscosimeter.

### (3. 2. 5. 2. 4) Solution Polymerization

One example of the solution polymerization may be, for example, a method in which a polymerization initiator is added to a mixed solution of monomers under a stream of an inert gas such as nitrogen, and the polymerization reaction is performed at a temperature of from 50° C. to 100° C. for a period of from 4 hours to 30 hours.

The polymerization initiator may be, for example, an azo-based polymerization initiator or a peroxide-based polymerization initiator. Examples of the azo-based polymerization initiator include 2,2′-azobisdimethylvaleronitrile (AIBN), 2,2′-azobis-2-methylbutyronitrile, dimethyl 2,2′-azobis(2-methylpropionate), and 4,4′-azobis-4-cyanovaleric acid. Examples of the peroxide-based polymerization initiator include benzoyl peroxide.

The content of the polymerization initiator is preferably from 0.01 parts by mass to 2.0 parts by mass, with respect to 100 parts by mass of the total amount of all the monomers constituting the (meth)acrylic acid alkyl ester copolymer.

In the solution polymerization, a chain transfer agent, an emulsifying agent and/or the like may be added to the mixed solution of monomers, in addition to the polymerization initiator. Any known compound(s) can be selected and used as appropriate, as the chain transfer agent, the emulsifying agent and/or the like.

The amount of the polymerization initiator remaining in the adhesive layer for a photomask is preferably small. This makes it possible to reduce the amount of outgas generated during exposure.

Examples of the method of reducing the amount of the polymerization initiator remaining in the adhesive layer for a photomask include: a method of reducing the amount of the polymerization initiator to be added at the time of polymerizing the (meth)acrylic acid alkyl ester copolymer, to a minimum level necessary: a method of using a polymerization initiator which is more susceptible to thermal decomposition: and a method of heating the adhesive to a high temperature for a long period of time, in the coating and drying processes of the adhesive, so that the polymerization initiator is decomposed in the drying process.

The term “10-hour half-life temperature” is used as an index indicating the thermal decomposition rate of the polymerization initiator. The term “half-life” refers to a period of time until half of the polymerization initiator is decomposed. The term “10-hour half-life temperature” refers to a temperature at which the half-life is 10 hours.

As the polymerization initiator, it is preferred to use a polymerization initiator having a lower 10-hour half-life temperature. The lower the 10-hour half-life temperature of the polymerization initiator is, the more susceptible the polymerization initiator is to thermal decomposition. As a result, the polymerization initiator is less likely to remain in the adhesive layer for a photomask.

The 10-hour half-life temperature of the polymerization initiator is preferably 80° C. or lower, and more preferably 75° C. or lower.

Examples of the azo-based polymerization initiator having a lower 10-hour half-life temperature include 2,2′-azobis(4-methoxy-2,4-dimethylvaleronitrile) (10-hour half-life temperature: 30° C.), 2,2′-azobisdimethylvaleronitrile (10-hour half-life temperature: 65° C.). 2.2-azobis(2,4-dimethylvaleronitrile) (10-hour half-life temperature: 51° C.), dimethyl 2,2′-azobis(2-methylpropionate) (10)-hour half-life temperature: 66° C.), and 2,2′-azobis(2-methylbutyronitrile) (10-hour half-life temperature: 67° C.).

Examples of the peroxide-based polymerization initiator having a lower 10-hour half-life temperature include dibenzoyl peroxide (10-hour half-life temperature: 74° C.), and dilauroyl peroxide (10-hour half-life temperature: 62° C.).

### (3. 2. 5. 2. 5) Crosslinking Agent

The acrylic adhesive preferably contains a reaction product of the (meth)acrylic acid alkyl ester copolymer and a crosslinking agent. This makes it possible to improve the cohesive force of the resulting adhesive layer for a photomask, to reduce the adhesive residue at the time of peeling the pellicle from the photomask, and to improve the adhesive force at a high temperature (for example, in a temperature environment of 60° C., or of higher than 60° C.).

The crosslinking agent contains at least one of an isocyanate group, an epoxy group, or acid anhydride.

The crosslinking agent may be, for example, a monofunctional epoxy compound, a multifunctional epoxy compound, an acid anhydride-based compound, a metal salt, a metal alkoxide, an aldehyde-based compound, a non-amino resin-based amino compound, a urea-based compound, an isocyanate-based compound, a metal chelate-based compound, a melamine-based compound, or an aziridine-based compound.

From the viewpoint of having an excellent reactivity with a functional group component included in the (meth)acrylic acid alkyl ester copolymer, in particular, the crosslinking agent is more preferably at least one of a monofunctional epoxy compound, a multifunctional epoxy compound, an isocyanate-based compound, or an acid anhydride-based compound, and still more preferably an acid anhydride-based compound.

Examples of the monofunctional epoxy compound include glycidyl (meth)acrylate, glycidyl acetate, butyl glycidyl ether, and phenyl glycidyl ether.

Examples of the multifunctional epoxy compound include neopentyl glycol diglycidyl ether, polyethylene glycol diglycidyl ether, bisphenol A diglycidyl ether, bisphenol F diglycidyl ether, phthalic acid diglycidyl ester, dimer acid diglycidyl ester, triglycidyl isocyanurate, diglycerol triglycidyl ether, sorbitol tetraglycidyl ether, N, N, N′, N′-tetraglycidyl m-xylenediamine, 1,3-bis(N,N-diglycidylaminomethyl)cyclohexane, and N,N,N′,N′-tetraglycidyl diaminodiphenylmethane.

Examples of the acid anhydride-based compound include an aliphatic dicarboxylic anhydride, and an aromatic polyvalent carboxylic anhydride.

Examples of the aliphatic dicarboxylic anhydride include maleic anhydride, hexahydrophthalic anhydride, hexahydro-4-methylphthalic anhydride, bicyclo[ 2.2. 1 ]heptane-2,3-dicarboxylic anhydride, 2-methylbicyclo[2.2.1 ]heptane-2,3-dicarboxylic anhydride, and tetrahydrophthalic anhydride.

Examples of the aromatic polyvalent carboxylic anhydride include phthalic anhydride, and trimellitic anhydride.

Examples of the isocyanate-based compound include xylylene diisocyanate, hexamethylene diisocyanate, and tolylene diisocyanate: and multimers, derivatives and polymerization products thereof. These compounds may be used singly, or in combination of two or more kinds thereof.

The crosslinking agent may be a commercially available product. The commercially available product of the crosslinking agent may be, for example, “RIKACID MH-700 G” manufactured by New Japan Chemical Co., Ltd. or the like.

The adhesive layer for a photomask contains a reaction product of the copolymer and the crosslinking agent, and the content of the crosslinking agent is preferably from 0.01 parts by mass to 3.00 parts by mass, with respect to 100 parts by mass of the total amount of the monomers constituting the copolymer.

The content of the crosslinking agent is preferably from 0.01 parts by mass to 3.00 parts by mass, with respect to 100 parts by mass of the total amount of the monomers constituting the copolymer: and the content is more preferably from 0.10 parts by mass to 3.00 parts by mass, and still more preferably from 0.1 parts by mass to 2.00 parts by mass, from the viewpoint of obtaining an adhesive layer for a photomask in which the adhesive residue is less likely to occur.

When the upper limit of the content of the crosslinking agent is 3.00 parts by mass or less, an excessive increase in the crosslinking density of the (meth)acrylic acid alkyl ester copolymer can be prevented. Therefore, it is thought that the adhesive absorbs the stress applied to the photomask, thereby alleviating the impact of the adhesive layer for a photomask on the flatness on the photomask. The upper limit of the content of the crosslinking agent is preferably 2.00 parts by mass or less, and more preferably 1.00 parts by mass or less.

When the lower limit of the content of the crosslinking agent is 0.01 parts by mass or more, on the other hand, an excessive decrease in the crosslinking density can be prevented. Therefore, it is thought that handleability during the production process is maintained, making the adhesive residue less likely to occur at the time of peeling the pellicle from the photomask.

It is possible to obtain a pellicle in which the occurrence of adhesive residue is further reduced, when the content of the crosslinking agent is within the range of from 0.01 parts by mass to 3.00 parts by mass.

### (3. 2. 5. 2. 6) Catalyst

The coating composition may further contain a catalyst. This makes it possible to further accelerate the curing of the (meth)acrylic acid alkyl ester copolymer.

The catalyst may be, for example, an amine-based catalyst. Examples of the amine-based catalyst include octylic acid salt of (1,8-diazabicyclo-(5.4.0)undecene-7), and triethylenediamine. The amine-based catalyst may be a commercially available product, such as “DBU”, “DBN”, “U-CAT”, “U-CAT SAI” or “U-CAT SA102”, manufactured by San-Apro Ltd.

The content of the catalyst is preferably from 0.01 parts by mass to 3.00 parts by mass, and more preferably from 0.10 parts by mass to 1.00 parts by mass, with respect to 100 parts by mass of the (meth)acrylic acid alkyl ester copolymer.

### (3. 2. 5. 2. 7) Surface Modifier

It is preferred that the coating composition does not contain a surface modifier. This makes it possible to reduce the amount of outgas to be generated.

### (3. 2. 5. 2. 8) Additive

If necessary, the coating composition may contain an additive(s) such as a filler, a pigment, a diluent, an anti-aging agent and/or a tackifier. Such additives may be used singly, or in combination of two or more kinds thereof.

### (3. 2. 5. 2. 9) Diluting Solvent

The coating composition may contain a diluting solvent. This allows the viscosity of the coating composition to be adjusted. As a result, the thickness and the width of the coating composition can be more easily controlled at the time of coating the coating composition on the end face for a photomask of the pellicle frame.

Examples of the diluting solvent include propyl acetate, acetone, ethyl acetate, and toluene.

The coating composition preferably has a viscosity of 50 Pa·s or less, more preferably from 10 Pa·s to 40 Pa·s, and still more preferably from 20 Pa·s to 30 Pa.s.

The viscosity of the coating composition is the viscosity thereof when the temperature of the coating composition is 25° C., and can be measured by a Type E viscosimeter

### (3. 3) Step of Forming Pellicle Film

The method of producing a pellicle according to the present disclosure may include a step of forming a pellicle film. The step of forming a pellicle film may be performed by a known method.

### (4) Method of Evaluating Pellicle Frame

A method of evaluating a pellicle frame according to the present disclosure is a method of evaluating a pellicle frame having a rectangular shape, the pellicle frame having: one end face to be provided with an adhesive layer capable of adhering to a photomask: and the other end face for supporting a pellicle film. This evaluation method includes measuring the amount of twist Δd of the one end face. The amount of twist Δd indicates the maximum value of the distance between a virtual plane that passes through three points, of four points at four corners of the one end face, and one remaining point.

Since the method of evaluating a pellicle frame according to the present disclosure has the configuration described above, it is possible to measure the amount of twist of the end face of the pellicle frame with high accuracy, and to evaluate a pellicle frame which facilitates reducing the distortion of a mask.

The pellicle frame to be measured may but need not contain quartz glass. The pellicle frame which does not contain quartz glass is the same as the above-described pellicle frame according to the present disclosure.

The expression “the amount of twist Δd of the one end face indicates the maximum value of the distance between a virtual plane that passes through three points, of four points at the four corners of the one end face, and one remaining point” has the same meaning as described above.

The amount of twist Δd of the one end face is measured as follows. Specifically, the pellicle frame is placed on a surface plate such that the end face of the pellicle frame different from the end face (hereinafter, also referred to as “end face on the measurement side”) on the side whose amount of twist is measured, of the pellicle frame, faces the surface plate. The height from the surface plate to each of the four points at the four corners of the end face on the measurement side, is measured using a 3D displacement meter. Subsequently, the measured values of the heights of the four points are used to obtain a virtual plane that passes through three points of the four points, and the shortest distance (hereinafter, also referred to as “first shortest distance”) between the thus obtained virtual plane and one remaining point is calculated. Since there are four patterns for obtaining a virtual plane from the four points, four first shortest distances are calculated. The maximum value of the four first shortest distances is defined as the amount of twist Δd of the end face on the measurement side.

Specifically, when the four corners of the end face on the measurement side are respectively defined as the points C1, C2, C3 and C4, the amount of twist Δd of the end face on the measurement side indicates the maximum value of the following first distance, second distance, third distance and fourth distance. The first distance refers to the shortest distance between the virtual plane that passes through the point C1, the point C2 and the point C3, and the point C4. The second distance refers to the shortest distance between the virtual plane that passes through the point C1. the point C2 and the point C4, and the point C3. The third distance refers to the shortest distance between the virtual plane that passes through the point C1, the point C3 and the point C4, and the point C2. The fourth distance refers to the shortest distance between the virtual plane that passes through the point C2, the point C3 and the point C4, and the point C1.

### EXAMPLES

The present disclosure will be described below in further detail. It is noted, however, the invention of the present disclosure is not limited to these Examples alone.

The methods of measuring: the amount of twist Δd and the TIR value of the end face for a photomask of the pellicle frame having a rectangular shape: the TIR value of the flat surface of a flat plate: the TIR value of the adhesive layer for a photomask, of the pellicle: the amount of twist Δd and the TIR value of the end face for a pellicle film; and the thickness of the adhesive layer for a photomask, of the pellicle, are as follows.

### Method of Measuring Amount of Twist Δd of End Face for Photomask

The amount of twist Δd of the end face for a photomask is determined as follows.

The pellicle frame is placed on a surface plate such that the end face for a pellicle film of the pellicle frame faces the surface plate. The height from the surface plate to each of the four points at the four corners of the end face for a photomask, is measured using a 3D displacement meter (“WI 5000”, sensor head “WI-004”: manufactured by Keyence Corporation). Subsequently, the measured values of the heights of the four points are used to obtain a virtual plane that passes through three points of the four points, and the shortest distance (hereinafter, also referred to as “first shortest distance”) between the thus obtained virtual plane and one remaining point is calculated. Since there are four patterns for obtaining a virtual plane from the four points, four first shortest distances are calculated. The maximum value of the four first shortest distances is defined as the amount of twist Δd of the end face for a photomask.

### Method of Measuring TIR Value of End Face for Photomask

The TIR value of the end face for a photomask is determined as follows.

The pellicle frame is placed on a surface plate such that the end face for a pellicle film of the pellicle frame faces the surface plate. The height from the surface plate to each of a total of 204 measurement points on the end face for a photomask is measured by a 3D displacement meter (“WI 5000”, sensor head “WI-004”: manufactured by Keyence Corporation). The 204 measurement points consist of four points at the four corners of the end face for a photomask, and 200 points on the four sides between the four corners. The 200 points are, in principle, the total of the points which are set at 2.5 mm intervals from one point of the four corners toward another point of the four corners, on each of the sides between the four corners. However, in a case in which the interval (hereinafter, also referred to as “corner interval”) between one point (hereinafter, also referred to as “corner point”) of the four corners and a point adjacent to the corner point, of the 200 points, is not 2.5 mm, the point adjacent to the corner point refers to a point which is set such that the corner interval is less than 2.5 mm. In a case in which the number of the measurement points which are set using the above-described 2.5 mm interval and corner interval, is not 204, due to the difference in the size of the pellicle frame, the 2.5 mm interval and the above-described approach of the corner interval are employed to determine the measurement points.

Subsequently, the least squares plane calculated using the measured values of the heights of the 204 points is obtained. The measurement point having the maximum difference in height, of the differences in height between a plurality of measurement points located on the side opposite to the side of the surface plate with respect to the least squares plane, and the least squares plane, is identified as “first measurement point”. The measurement point having the maximum difference in height, of the differences in height between a plurality of measurement points located on the side of the surface plate with respect to the least squares plane, and the least squares plane, is identified as “second measurement point”. The sum of the difference in height from the least squares plane at the first measurement point and the difference in height from the least squares plane at the second measurement point, is defined as the TIR value.

### Method of Measuring TIR Value of Flat Surface of Flat Plate

The TIR value of the flat surface of the flat plate is measured in the same manner as the method of measuring the TIR value of the end face for a photomask, except that the pellicle frame is placed on the surface plate such that the surface of the flat plate opposite to the flat surface faces the surface plate, and that the height is measured on the flat surface, instead of the end face for a photomask.

### Method of Measuring TIR Value of Adhesive Layer for Photomask

The TIR value of the adhesive layer for a photomask is measured in the same manner as the method of measuring the TIR value of the end face for a photomask, except that the pellicle frame with an adhesive layer is placed on the surface plate such that the end face for a pellicle film of the pellicle frame with an adhesive layer faces the surface plate, and that the height is measured on the surface of the adhesive layer for a photomask, instead of the end face for a photomask.

### Method of Measuring Amount of Twist Δd of End Face for Pellicle Film

The amount of twist Δd of the end face for a pellicle film is measured in the same manner as the method of measuring the amount of twist Δd of the end face for a photomask, except that the pellicle frame is placed on the surface plate such that the end face for a photomask of the pellicle frame faces the surface plate, and that the height is measured on the end face for a pellicle film, instead of the end face for a photomask.

### Method of Measuring TIR Value of End Face for Pellicle Film

The TIR value of the end face for a pellicle film is measured in the same manner as the method of measuring the TIR value of the end face for a photomask, except that the pellicle frame is placed on the surface plate such that the end face for a photomask of the pellicle frame faces the surface plate, and that the height is measured on the end face for a pellicle film, instead of the end face for a photomask.

### Method of Measuring Thickness of Adhesive Layer for Photomask

The thickness of the adhesive layer for a photomask is determined as follows.

The pellicle frame with an adhesive layer is placed on a surface plate such that the end face for a pellicle film of the pellicle frame with an adhesive layer faces the surface plate. The height from the surface plate to each of six measurement points on one arbitrary side of the sides between the four corners of the end face for a photomask is measured by a 3D displacement meter (“WI 5000”, sensor head “WI-004”; manufactured by Keyence Corporation). In the width direction of the pellicle frame (namely, the shorter direction of one side of the pellicle frame), four of the six measurement points are the points coated with the adhesive layer, and two of the six measurement points are the points not coated with the adhesive layer.

In the present Examples, the adhesive layer for a photomask is formed only on the central portion of each of the sides between the four corners of the end face for a photomask, and is not formed on the marginal portion on the side of the through-hole of the pellicle frame and the marginal portion on the side opposite to the through-hole of the pellicle frame, of each of the sides between the four corners. Therefore, in the present Examples, the four points located at the central portion in the width direction of the pellicle, of the six measurement points, are defined as the locations where the adhesive layer for a photomask is formed on the end face for a photomask. The remaining two points located at both marginal portions in the width direction of the pellicle, of the six measurement points, are defined as the locations where the adhesive layer for a photomask is not formed on the end face for a photomask.

The measured values of the heights of the six points are used to calculate the difference in height between the point having the maximum height (the point at which the adhesive layer for a photomask has the maximum thickness), of the four points coated with the adhesive layer for a photomask, and the point having the minimum height, of the two points not coated with the adhesive layer for a photomask. The above-described calculation method is used to perform the measurement (at every 2.5 mm interval and corner interval) in the length direction of the pellicle (namely, the longer direction of one side of the pellicle frame), using the same approach as the measurement points for the TIR value of the end face for a photomask. The difference in height is measured in the same manner, for each of the remaining three sides between the four corners of the end face for a photomask. The mean value of the thus calculated differences in height of all the four sides is defined as the thickness of the adhesive layer for a photomask.

### Example 1

### Preparation Step

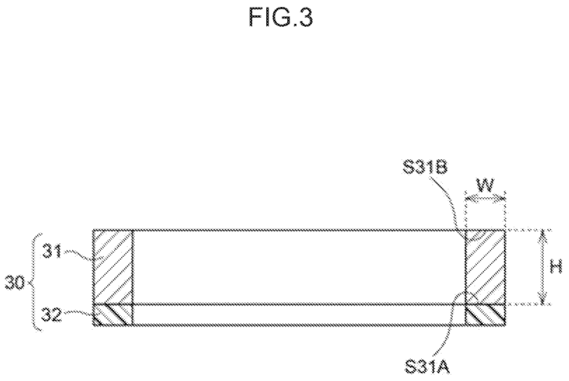

Example 1 will be described with reference to FIG. 3. FIG. 3 is a schematic cross-sectional view showing a cross section of a pellicle frame 30 with an adhesive layer, according to Example 1.

As shown in FIG. 3, a pellicle frame 31 (external dimensions: 151 mm×119 mm, frame height H: 1.4 mm, frame width W: 4 mm, made of SUS 304, mass: 18 g) having a rectangular shape was prepared. The amount of twist Δd and the TIR value of an end face S31A for a photomask, of the pellicle frame 31, were measured. The measured results of the amount of twist Δd and the TIR value of the end face S31A for a photomask, of the pellicle frame 31, are shown in Table 1. SUS 304 has a Young's modulus of 193 GPa.

### Preparation of Coating Composition

A styrene-based adhesive as the coating composition was prepared as follows.

Various components shown below were used as raw materials of the styrene-based adhesive.

### (Styrene-based Thermoplastic Elastomer (A))

H-SIS: a styrene-hydrogenated isoprene-styrene block copolymer (brand name: “HYBRAR 7125” (manufactured by Kuraray Co., Ltd.))

### (Tackifying Resin (B))

A hydride of an alicyclic petroleum resin: a C9-based hydrogenated petroleum resin (brand name: “ALCONP-100” (manufactured by Arakawa Chemical Industries, Ltd.), softening point: 100±5° C., number average molecular weight (Mn): 610) (Softener)
A paraffin-based mineral oil (brand name: “NEOVAC MR-200” (manufactured by MORESCO Co., Ltd.))

A quantity of 100 parts by mass of the styrene-based thermoplastic elastomer (A), 100 parts by mass of the tackifying resin (B), and 60 parts by mass of the softener were mixed to a total amount of 48 g, to obtain a raw material mixture. The thus obtained raw material mixture was introduced into a LABO PLASTOMILL (capacity: 60 mL: manufactured by Toyo Seiki Co., Ltd.), and then sealed. The mixture was kneaded at 200° C. and 100 rpm, for 20) minutes, to obtain a coating composition in the form of a lump. A quantity of about 10 g of the coating composition in the form of a lump was introduced into a heating tank (tank internal temperature: 200° C.), and melted. In this manner, the coating composition of the styrene-based adhesive was obtained.

### Step of Forming Adhesive Layer

The pellicle frame 31 was washed with pure water. The coating composition prepared as described above was coated on the end face S31A for a photomask, of the pellicle frame 31, using a dispenser, to form a coating layer. At this time, the coating composition was coated only on the region of the central portion of each of the sides between the four corners of the end face for a photomask. In this manner, a pellicle frame with a coating layer was obtained.

A first glass substrate was prepared as the flat plate. The TIR value of the flat surface of the flat plate was 5 μm. The placing method was performed. Specifically, the pellicle frame with a coating layer was placed on the flat plate in a state where a liner was pasted on the surface of the coating layer, such that the coating layer pasted with the liner, of the pellicle frame, and the flat surface of the flat plate were in contact with each other via the liner, with the coating layer of the pellicle frame with a coating layer facing the downward direction (direction of gravity). At this time, a pressure (load) was applied such that a pressure (load) of 423 g/cm² was uniformly applied over the entire coating layer of the pellicle frame with a coating layer. In this manner, a first contact article was obtained.

A first oven (“PVC-211”, manufactured by ESPEC) was prepared as a heating apparatus. The first contact article was placed in the first oven. The entire first contact article was heated by the first oven at a temperature of from 80 to 110° C. for 5 minutes. Subsequently, the first contact article was taken out of the heating apparatus, and the first flat plate was removed from the first contact article, to obtain the pellicle frame with a coating laver.

A second glass substrate was prepared as the substrate. The pellicle frame with a coating layer was placed on the substrate such that the coating layer of the pellicle frame with a coating layer were in contact with the substrate via the liner. Hereinafter, an article in which the substrate and the pellicle frame with a coating layer are layered one on another in the order mentioned is also referred to as “second contact article”.

A second oven (“PVC-211”, manufactured by ESPEC) was prepared. The second contact article was placed in the second oven. The entire second contact article was baked in the second oven at a temperature of 80° C. for 48 hours. Subsequently, the second contact article was taken out of the second oven, and the substrate was removed from the second contact article. In this manner, the pellicle frame 30 with an adhesive layer was obtained. At the time of baking, the entire second contact article was baked while applying a load of 18 g, including the weight of the pellicle frame.

An adhesive layer 32 for a photomask, of the pellicle frame 30 with an adhesive layer, had a thickness of 250 μm. The TIR value of the adhesive layer 32 for a photomask, of the pellicle frame 30 with an adhesive layer, was measured. The measured result of the TIR value of the adhesive layer 32 for a photomask, of the pellicle frame 30 with an adhesive layer, is shown in Table 1.

### Example 2 and Example 3, and Comparative Example 1

In each of Examples and Comparative Example, the pellicle frame 30 with an adhesive layer was obtained in the same manner as in Example 1, except that the pellicle frame as shown in Table 1 was prepared. The measured results of the amount of twist Δd and the TIR value of the end face S31A for a photomask, of the pellicle frame 31, and the TIR value of the adhesive layer 32 for a photomask, of the pellicle frame 30 with an adhesive layer, are shown in Table 1.

### Comparative Example 2

The pellicle frame 30 with an adhesive layer was obtained in the same manner as in Example 1, except that the pellicle frame as shown in Table 1 was prepared, and that the entire second contact article was baked while applying a load of 9 g, including the mass of the pellicle frame, at the time of baking. The measured results of the amount of twist Δd and the TIR value of the end face S31A for a photomask, of the pellicle frame 31, and the TIR value of the adhesive layer 32 for a photomask, of the pellicle frame 30 with an adhesive layer, are shown in Table 1. The mass the pellicle frame 31 made of titanium was 9 g.

### Example 4

The pellicle frame 30 with an adhesive layer was obtained in the same manner as in Example 1, except that the pellicle frame as shown in Table 1 was prepared, and that the first contact article was heated using a hot plate (“EC-1200 NR”, manufactured by AS ONE Corporation), as will be described later. The measured results of the amount of twist Δd and the TIR value of the end face S31A for a photomask, of the pellicle frame 31, and the TIR value of the adhesive layer 32 for a photomask, of the pellicle frame 30 with an adhesive layer, are shown in Table 1.

In Example 4, the first contact article was heated using the hot plate. Specifically, the first contact article was prepared so as to be in a state where the pellicle frame was arranged on the flattening article by the placing method, and the first contact article was placed on the plate of the hot plate such that the flattening article and the plate were in contact with each other.

### Example 5, Comparative Example 3, and Comparative Example 4

In each of Example and Comparative Examples, the pellicle frame 30 with an adhesive layer was obtained in the same manner as in Example 4, except that the pellicle frame as shown in Table 1 was prepared. For each example, the measured results of the amount of twist Δd and the TIR value of the end face S31A for a photomask, of the pellicle frame 31, and the TIR value of the adhesive layer 32 for a photomask, of the pellicle frame 30 with an adhesive layer, are shown in Table 1. Titanium has a Young's modulus of 106 GPa.

### Example 6 and Example 7

In each example, the pellicle frame 30 with an adhesive layer was obtained in the same manner as in Example 1, except that the pellicle frame as shown in Table 1 was prepared. For each example, the measured results of the amount of twist Δd and the TIR value of the end face S31A for a photomask, of the pellicle frame 31, and the TIR value of the adhesive layer 32 for a photomask, of the pellicle frame 30 with an adhesive layer, are shown in Table 1.

TABLE 1

| | Preparation Step | | | | Pellicle Frame with | |
|---|---|---|---|---|---|---|
| | Pellicle Frame | | | Step of Forming | Adhesive Layer | |
| | | TIR | | Adhesive Layer | Adhesive Layer | |
| | | value | | Flattening | TIR Value of Adhesive | |
| | Δd | of Frame | | Heating | Layer | Flattening |
| | (μm) | (μm) | Type | apparatus | (μm) | Rate |
| Example 1 | 1.0 | 27.0 | SUS | Oven | 9.1 | 0.66 |
| Comparative | 34.9 | 35.3 | SUS | Oven | 18.3 | 0.48 |
| Example 1 | | | | | | |
| Example 2 | 8.0 | 20.4 | SUS | Oven | 8.8 | 0.57 |
| Example 3 | 5.1 | 33.3 | SUS | Oven | 9.7 | 0.71 |
| Example 4 | 6.0 | 25.9 | SUS | Hot Plate | 9.3 | 0.64 |
| Comparative | 50.3 | 42.5 | Ti | Oven | 32.3 | 0.24 |
| Example 2 | | | | | | |
| Comparative | 23.4 | 26.5 | Ti | Hot Plate | 30.8 | −0.16 |
| Example 3 | | | | | | |
| Example 5 | 0.2 | 23.4 | Ti | Hot Plate | 9.3 | 0.60 |
| Example 6 | 3.2 | 20.4 | Ti | Oven | 9.6 | 0.53 |
| Example 7 | 2.8 | 34.5 | Ti | Oven | 7.0 | 0.80 |
| Comparative | 16.8 | 25.2 | Ti | Hot Plate | 15.4 | 0.39 |
| Example 4 | | | | | | |

In Table 1, the symbol “Δd” indicates the amount of twist Δd of the end face for a photomask of the pellicle frame. In Table 1, the term “TIR Value of Frame” indicates the TIR value of the end face for a photomask of the pellicle frame. In Table 1, the term “TIR Value of Adhesive Layer” indicates the TIR value of the adhesive layer for a photomask. In Table 1, the term “Flattening Rate” is represented by the following Equation (1):

Equation (1): Flattening rate)=1−(TIR value of adhesive layer for photomask/TIR value of end face for photomask)

In the pellicle frame of each of Example 1 to Example 7, the amount of twist Δd of the end face S31A for a photomask was 10 μm or less. Therefore, the TIR value of the adhesive layer 32 for a photomask, of the pellicle frame 30 with an adhesive layer, was less than 10 μm. The TIR value of a photomask is about several μm. In other words, the results revealed that the pellicle frame of each of Example 1 to Example 7 makes it possible to form an adhesive layer 32 for a photomask, which layer has a TIR value closer to that of a photomask, even in a case in which the adhesive layer 32 for a photomask has a small thickness. This means that, when the pellicle including the pellicle frame of any one of Example 1 to Example 7 is attached to a photomask, the flatness of the photomask is less likely to change. As a result, it has been found out that the use of the pellicle frame of any one of Example 1 to Example 7 allows for reducing the distortion of a photomask due to attaching the resulting pellicle to the photomask, even in a case in which the adhesive layer 32 for a photomask has a small thickness.

In the pellicle frame of each of Example 1 to Example 7, the amount of twist Δd of the end face S31A for a photomask was 10 μm or less. Therefore, the flattening rate was 50% or more, which is higher than that of a conventional pellicle frame. In other words, the results revealed that the pellicle frame of each of Example 1 to Example 7 makes it possible to form an adhesive layer 32 for a photomask, which layer has a higher flatness, even in a case in which the end face S31A for a photomask does not have a high flatness.

In the pellicle frame of each of Comparative Example 1 to Comparative Example 4, the amount of twist Δd of the end face for a photomask was more than 10 μm. Therefore, the TIR value of the adhesive layer for a photomask of the pellicle frame with an adhesive layer was more than 10 μm. In other words, the results revealed that the pellicle frame of each of Comparative Example 1 to Comparative Example 4 does not make it possible to form an adhesive layer for a photomask, which layer has a TIR value closer to that of a photomask, in a case in which the adhesive layer for a photomask has a small thickness. This means that, when the pellicle including the pellicle frame of any one of Comparative Example 1 to Comparative Example 4 is attached to a photomask, the flatness of the photomask is more likely to change. As a result, it has been found out that the use of the pellicle frame of any one of Comparative Example 1 to Comparative Example 4 does not allow for reducing the distortion of a photomask due to attaching the resulting pellicle to the photomask.

The disclosure of Japanese Patent Application No. 2021-148631 filed on Sep. 13, 2021 is incorporated herein by reference in their entirety.

All publications, patent applications, and technical standards mentioned in the present specification are incorporated herein by reference to the same extent as if each individual publication, patent application, or technical standard was specifically and individually indicated to be incorporated by reference.

1. A pellicle frame (excluding a pellicle frame containing quartz glass) having a rectangular-shape, the pellicle frame having:
one end face to be provided with an adhesive layer capable of adhering to a photomask; and
another end face for supporting a pellicle film;
wherein the one end face has an amount of twist Δd of 10 μm or less, and
wherein the amount of twist Δd of the one end face indicates a maximum value of a distance between a virtual plane that passes through three points, of four points at four corners of the one end face, and one remaining point.

2. The pellicle frame according to claim 1, wherein the other end face has an amount of twist Δd of 10 μm or less, and
wherein the amount of twist Δd of the other end face indicates a maximum value of a distance between a virtual plane that passes through three points, of four points at four corners of the other end face, and one remaining point.

3. The pellicle frame according to claim 1, wherein the pellicle frame comprises a metal.

4. The pellicle frame according to claim 1, wherein the pellicle frame comprises at least one selected from the group consisting of aluminum, titanium, stainless steel, a carbon-based material, a resin, silicon and a ceramic-based material.

5. The pellicle frame according to claim 1, wherein the pellicle frame has a Young's modulus of 90 GPa or more.

6. The pellicle frame according to claim 1, wherein the amount of twist Δd of the one end face is 1 μm or more.

7. The pellicle frame according to claim 1, wherein the one end face has a TIR value of 30 μm or less.

8. The pellicle frame according to claim 1, wherein the other end face has a TIR value of 30 μm or less.

9. A pellicle comprising:
the pellicle frame according to claim 1;
the adhesive layer provided on the one end face; and
the pellicle film supported on the other end face.

10. A method of producing a pellicle, the method comprising:
preparing the pellicle frame according to claim 1;and
forming the adhesive layer, by coating a coating composition on the one end face to form a coating layer, heating the coating layer in a state in which the coating layer is brought into contact with a flat surface of a flattening article, and then baking the coating layer;
wherein the adhesive layer has a thickness of from 10 μm to 500 μm, and
wherein the flat surface has a TIR value of less than 10 μm.

11. The method of producing a pellicle according to claim 10, comprising fixing three points, of four points at four corners of the one end face of the pellicle frame having a rectangular shape, and applying a force to one remaining point.

12. A method of evaluating a pellicle frame having a rectangular shape, the pellicle frame having: one end face to be provided with an adhesive layer capable of adhering to a photomask; and another end face for supporting a pellicle film;
wherein the method comprises measuring an amount of twist Δd of the one end face, and
wherein the amount of twist Δd indicates a maximum value of a distance between a virtual plane that passes through three points, of four points at four corners of the one end face, and one remaining point.
